(19) United States
(12) Patent Application Publication
(10) Pub. No.: US 2006/0076654 A1
(43) Pub. Date: Apr. 13, 2006

(54) Lead frame and physical amount sensor

(75) Inventor: Masayoshi Omura, Hamamatsu-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignee: YAMAHA CORPORATION

(21) Appl. No.: 11/244,419

(22) Filed: Oct. 4, 2005

(30) Foreign Application Priority Data
Oct. 5, 2004 (JP) P2004-292468
Oct. 22, 2004 (JP) P2004-308360
Nov. 2, 2004 (JP) 2004-319068

(51) Int. Cl. H01L 23/495

(52) U.S. Cl. 257/666

(57) ABSTRACT

A lead frame for a physical sensor is made of sheet metal and includes a stage for mounting a physical sensor chip, a frame having a plurality of leads disposed peripherally around the stage, and a pair of connecting members which connect the frame and the stage and are oppositely disposed at a proximal edge of the stage. The stage is deformable so as to rotate around an axis connecting the pair of connecting members. The lead frame also has a plate-like bending member which is provided on a bottom side of the stage at the proximal edge thereof and is bent to an angle with the bottom side of the stage of up to 90°.

Priority is claimed on Japanese Patent Application No. 2004-292468, filed Oct. 5, 2004, Japanese Patent Application No. 2004-308360, filed Oct. 22, 2004, and Japanese Patent Application No. 2004-319068, filed Nov. 2, 2004, the contents of which are incorporated herein by reference.

### BACKGROUND OF THE INVENTION

1. Field of the Invention

The present invention relates to a physical sensor for measuring the azimuth or orientation of a physical quantity such as magnetism or gravity, and to a lead frame used in such a physical sensor.

2. Description of Related Art

Cell phones and other handheld devices equipped with a global positioning system (GPS) function which displays information on the user's position have appeared on the market in the past few years. In addition to a GPS function, by also providing such devices with a function that accurately detects geomagnetism or a function that detects the rate of acceleration, it is possible to sense the azimuth, orientation, or direction of travel within three-dimensional space of a handheld device held by a user.

To provide a handheld device with the above functions, it is necessary to build a physical sensor such as a magnetic sensor or an acceleration sensor into the terminal. Moreover, the detection of azimuth or acceleration in three-dimensional space with such a physical sensor requires that the surface on which the physical sensor chip is installed be tilted.

A variety of such physical sensors have been described to date. For example, one known magnetic sensor differs from the above construction by having two magnetic sensor chips mounted on a surface that is not tilted. This magnetic sensor has mounted on a substrate a first magnetic sensor chip (physical sensor chip) which is sensitive to the magnetic components of an external magnetic field in two mutually orthogonal directions along the surface of the substrate (X and Y directions), and a second magnetic sensor chip which is sensitive to the magnetic component of the external magnetic field in a direction orthogonal to the surface of the substrate (Z direction). Based on the magnetic components detected by this pair of magnetic sensor chips, the magnetic sensor measures geomagnetic components as vectors in three-dimensional space.

However, in such a magnetic sensor, the second magnetic sensor chip is mounted so as to stand perpendicular to the surface of the substrate, which has the undesirable effect of increasing the thickness of the sensor (height in the Z direction). To minimize this thickness, Japanese Unexamined Patent Application, First Publication, Nos. (JP-A) 9-292408, JP-A 2002-156204 and JP-A 2004-128473 describe sensors in which, as mentioned above, the physical sensor chips are mounted on a tilted surface.

At the interior of these physical sensors, a plurality of physical sensor chips, such as magnetic sensor chips, are arranged so as to be mutually tilted. By mutually tilting the physical sensor chips in this way, it is possible to detect the magnetic components in three directions (the mutually orthogonal X and Y directions which lie along the horizontal plane, and the Z direction which is orthogonal to the X and Y directions) and to measure the geomagnetic direction from the respective measured values as a vector in three-dimensional space. In particular, because the physical sensor chips are tilted, the height of the sensor in the Z direction can be reduced, enabling the sensor thickness to be minimized.

The angle between these two tilted planes is set within a range of 0 to 90°, with an angle of at least 20° being preferred, and an angle of at least 30° being even more preferred. The larger the angle, the better the detection sensitivity in the Z direction (due to separation from the X and Y axes).

In addition to minimizing thickness, a physical sensor in which the physical sensor chips are tilted provides other advantages as well. Specifically, in an acceleration sensor (physical sensor) having a one-sided beam structure like that described in JP-A 9-292408, an acceleration sensor chip (physical sensor chip) is tilted beforehand with respect to the mounting substrate. By placing the sensor packaging on the surface of a mounting substrate, this acceleration sensor can maintain a high sensitivity in a given axial direction according to the direction of tilt and reduce the sensitivity in the other axial directions.

Physical sensors in which the physical sensor chips have been mutually tilted as described above are likely to predominate in the future, both because the thickness of the sensor can be minimized, enabling low-profile physical sensors to be achieved, and because of the various advantages associated with such tilting.

Physical sensors in which such physical sensor chips are mutually tilted are described more fully below in conjunction with FIG. 61, which shows physical sensor chips 303 mounted on stages 302 in a lead frame. The stages 302 have a tilt supported by projecting members 305 that are formed so as to project down toward the bottom side of a molded resin body 307 which integrally fixes the physical sensor chips 303 and the lead frame.

The stages 302 are formed together with the lead frame by pressworking or otherwise shaping thin-gauge sheet metal. Next, projecting members 305 which project out on the bottom side of the stages 302 are formed at the distal edges of the stages 302. The lead frame is clamped from above and below between mold halves of predetermined shapes and fixed in place. At this time, the surface of one of the mold halves pushes against the distal edges of the projecting members 305, causing each stage 302 to bend in such a way as to rotate around an axis which joins a pair of connecting members connected to the proximal edge of the stage 302 and assume a tilted state like that shown in FIG. 61. Resin is then injected into the mold interior, thereby fixing the components within the mold.

The stages 302 thus take on a shape in which the distal edges thereof are tilted toward the top side of the molded resin body 307, and the tilt is supported by the projecting members 305.

The above-described physical sensor is used, for example, to provide handheld devices such as cell phones with a navigation function. Therefore, as handheld devices become increasingly smaller, there exists a need to further miniaturize such physical sensors. At the same time, there also exists a need to achieve a higher level of detection accuracy.

This is because it is necessary to precisely measure three-dimensional physical values such as the attitude (including angle of tilt) of the handheld device—including the angle at which the user is leaning and how the user is holding the handheld device—to accurately display GPS function-based map information utilizing geomagnetism.

In particular, given their mobility and convenience, handheld devices are not limited only to use as personal devices; commercial and business applications are also notable. For example, in work such as building maintenance or taking inventory, the user carries out the work while moving between multiple buildings and from floor to floor within a building. The ability to accurately measure three-dimensional physical values even in such circumstances enables the user to know precisely his or her current position, thus making it possible to smoothly and efficiently carry out the work and enhancing ease of use. These reasons further underscore the need to, as noted above, enhance the detection accuracy in physical sensors.

### SUMMARY OF THE INVENTION

Therefore, an object of the present invention is to provide a lead frame and a physical sensor which, by ensuring the tilt angle of a stage therein, can enhance the detection sensitivity in the Z direction by a physical sensor chip; that is, a lead frame and a physical sensor which are capable of measuring physical values to a high precision in all directions in three-dimension space.

To achieve the above object, the lead frame made of sheet metal according to the present invention includes a stage with a top side for mounting a physical sensor chip thereon, a frame having a plurality of leads disposed peripherally around the stage, a pair of connecting members which connect the frame and the stage, are oppositely disposed across the stage at a proximal edge thereof, and are adapted for deforming the stage about an axis that mutually connects the connecting members, and a plate-like bending member which is provided on a bottom side of the stage at the proximal edge thereof and is bent to an angle with the bottom side of the stage of up to 90°.

When the lead frame according to this invention is clamped from above and below within a mold of a specific shape, the surface of the mold pushes against the bending member, pushing up the stage. As a result, the stage deforms around an axis connecting the pair of connecting members, causing the stage to assume a tilted state in which the distal edge of the stage faces upward. The stage tilts until the plate-like bending member comes into planar contact with the surface of the mold, at which point deformation stops. In this state, the surface of the plate-like bending member is parallel to the top side of the stage prior to rotation, and an acute angle is maintained between the bending member and the stage.

After reaching this state, because the bending member has been shaped by being bent at the proximal edge of the stage, it tries to return to its original state by elastic recovery. However, the bending member is in planar contact with the mold and so does not elastically deform. This elastic deformation force thus acts upon the stage so as to return the stage to its original position relative to the bending member. As a result, the stage tries to deform further around the axis in a direction that increases the angle between the stage and the bending member; that is, the stage tries to deform in a direction that increases the tilt angle. The stage is subsequently fixed by molding resin that has been injected into the mold interior.

In this way, before the molding resin hardens, the tilt angle of the stage, instead of becoming shallower (smaller) as in the prior art, easily deforms so as to become deeper (larger). This makes it possible to prevent a decrease in the detection sensitivity of the physical sensor chip in the Z direction; i.e., in the direction perpendicular to the sheet metal.

In the lead frame of the invention, it is preferable for the stage to have a top projecting member which projects out on the top side of the stage.

In a lead frame having this configuration, because a top projecting member and a bottom bending member are formed on the stage, when the lead frame is clamped under pressure from above and below in a mold of a specific shape, the stage is pushed by the top projecting member and the bottom bending member and thus deforms and tilts by rotating around an axis connecting the pair of connecting members. Because the stage tilts at this time while held from above and below between the top projecting member and the bottom bending member, the tilted state is stable.

Thus, before becoming fixed by molding resin or the like, the stage has a stable tilted state. Moreover, because the stage can easily be adjusted to a desired tilt angle by the top projecting member and the bottom bending member, the tilt precision is enhanced. Also, because the stage is held from above and below, the stage can be prevented from rising upward. As a result, a decrease in the detection sensitivity of the physical sensor chip in the Z direction (direction perpendicular to the sheet metal) can be prevented.

The physical sensor of the invention which is manufactured using the above-described lead frame includes the above-described stage, the above-described physical sensor chip installed on the top side or bottom side of the stage, leads which are electrically connected to the physical sensor chip, and a molded resin body which integrally fixes the stage, the physical sensor chip and the leads.

In the physical sensor according to this invention, use is made of a lead frame which readily deforms so that the tilt angle of the stage prior to hardening of the resin becomes larger rather than smaller. As a result, a decrease in detection sensitivity in the direction perpendicular to the sheet metal can be prevented and physical values such as magnetism can be measured to a high accuracy in all directions in three-dimensional space.

The invention also provides a lead frame which is made of sheet metal and includes a stage for mounting a physical sensor chip, a frame having a plurality of leads disposed near the stage, and a connecting member which connects the frame and the stage and has a deforming portion. The stage has a top projecting member which projects out at a tilt on a top side of the stage. Moreover, the stage is set so that a line segment connecting distal and proximal ends of the projecting member forms an acute angle with a line segment connecting the proximal end of the top projecting member and the deforming portion.

In this lead frame according to the present invention, when the distal end of the top projecting member is pushed by the mold from the top side toward the bottom side of the stage, force is applied at the distal end and the deforming portion of the connecting member serves as the fulcrum, causing a force to act upon the proximal end of the top projecting member. Hence, based on the principle of a lever, the deforming portion deforms and the stage rotates precisely a given angle about an axis which includes this deforming portion, thus tilting with respect to the frame.

Resin molding is administered in this state. When resin molding has been completed, the distal end of the top projecting member is disposed on the top side of the molded resin body.

The present invention further provides a physical sensor which is manufactured using a lead frame made of sheet metal and includes a stage for mounting a physical sensor chip, a frame having a plurality of leads disposed near the stage, and a connecting member that connects the frame and the stage and has a deforming portion, in which the physical sensor chip is mounted at the stage, and in which the physical sensor chip and the leads are electrically connected, and the stage, the physical sensor chip, the frame having a plurality of leads and the connecting member are integrally fixed within a molded resin body. In this physical sensor, the stage has a projecting member which is tilted with respect to the stage and extends to substantially a top side of the molded resin body; the stage is tilted with respect to a bottom side of the molded resin body about an axis composed in part of the deforming portion on the connecting member; and a line segment connecting distal and proximal ends of the projecting member forms an acute angle with a line segment connecting the proximal end of the projecting member and the deforming portion of the connecting member.

Still further, according to the present invention, a physical sensor chip packaging process is provided which includes the steps of mounting a physical sensor chip in the foregoing lead frame, then molding resin about the mounted physical sensor chip. In this process, closing a mold for molding the resin causes the projecting member to come into contact with and press against an inside face of the mold, thereby deforming the deforming portion of the connecting member and tilting the stage. Resin molding is carried out with the stage held in a tilted state.

In this physical sensor chip packaging process, closing the mold for resin molding brings the projecting member into contact with, and presses it against, the inside face of the mold. When this happens, the deforming portion of the connecting member deforms so that the stage rotates about an axis which includes this deforming portion, placing the stage in a tilted state with respect to the frame. Resin molding is carried out in this state.

### BRIEF DESCRIPTION OF THE DRAWINGS

FIG. 1 is a plan view of a magnetic sensor according to a first embodiment of the invention.

FIG. 2 is a sectional side view of a magnetic sensor according to the first embodiment of the invention.

FIG. 3 is a plan view of a lead frame according to the first embodiment of the invention.

FIG. 4 is a cross-sectional view along line E-E of the lead frame shown in FIG. 3.

FIG. 5 is a plan view in which the bending members of the lead frame shown in FIG. 3 have been bent.

FIG. 6 is a cross-sectional view along line F-F of the lead frame shown in FIG. 5.

FIG. 7 is a sectional view illustrating a step in the manufacture of the magnetic sensor shown in FIG. 1.

FIG. 8 is a plan view of a first variation of the bending members in the lead frame shown in FIG. 3.

FIG. 9 is a plan view of a second variation of the bending members in the lead frame shown in FIG. 3.

FIG. 10 is a plan view of a third variation of the bending members in the lead frame shown in FIG. 3.

FIG. 11 is sectional side view of a magnetic sensor manufactured from the lead frame shown in FIG. 10.

FIG. 12 is a sectional side view of a magnetic sensor according to a second embodiment of the invention.

FIG. 13 is a sectional side view of a magnetic sensor according to a third embodiment of the invention.

FIG. 14 is a sectional side view of a magnetic sensor according to a fourth embodiment of the invention.

FIG. 15 is a plan view of an example of a lead frame that can be used when manufacturing the magnetic sensor shown in FIG. 14.

FIG. 16 is a plan view of a variation of the bottom projecting members in the lead frame shown in FIG. 15.

FIG. 17 is a plan view of another variation of the bottom projecting members in the lead frame shown in FIG. 15.

FIG. 18 is a plan view of a magnetic sensor according to a fifth embodiment of the invention.

FIG. 19 is a sectional side view of the magnetic sensor according to the fifth embodiment of the invention.

FIG. 20 is a plan view of a lead frame used in the manufacture of the magnetic sensor shown in FIG. 18.

FIG. 21 is a sectional view illustrating a step in the manufacture of the magnetic sensor shown in FIG. 18.

FIG. 22 is a sectional side view of a magnetic sensor according to a sixth embodiment of the invention.

FIG. 23 is a plan view of a variation of the top projecting members in the lead frame shown in FIG. 20.

FIG. 24 is a sectional side view of a magnetic sensor manufactured using the lead frame shown in FIG. 23.

FIG. 25 is a sectional side view of a magnetic sensor manufactured using a variation of the lead frame shown in FIG. 23.

FIG. 26 is a plan view of a variation of the bottom bending members in the lead frame shown in FIG. 23.

FIG. 27 is a sectional side view of a magnetic sensor manufactured using the lead frame shown in FIG. 26.

FIG. 28 is a sectional side view of a magnetic sensor according to a seventh embodiment of the invention.

FIG. 29 is a plan view of a lead frame that may be used when manufacturing the magnetic sensor shown in FIG. 28.

FIG. 30 is a sectional view along line G-G of the lead frame shown in FIG. 29.

FIG. 31 is a plan view showing the bottom bending members in the bent state within the lead frame shown in FIG. 29.

FIG. 32 is a sectional view along line H-H of the lead frame shown in FIG. 31.

FIG. 33 is a sectional side view of a variation in the bottom bending members in the lead frame shown in FIG. 29.

FIG. 34 is a sectional side view of a magnetic sensor manufactured with a lead frame having the bottom bending members shown in FIG. 33.

FIG. 35 is a plan view of another variation of the bottom bending members in the lead frame shown in FIG. 29.

FIG. 36 is a plan view of a variation of the top projecting members in the lead frame shown in FIG. 35.

FIG. 37 is a sectional side view of a magnetic sensor manufactured with the lead frame shown in FIG. 36.

FIG. 38 is a plan view of another variation of the top projecting members in the lead frame shown in FIG. 35.

FIG. 39 is a plan view of another variation of the top projecting members in the lead frame shown in FIG. 35.

FIG. 40 is a sectional view of a physical sensor according to an eighth embodiment of the invention.

FIG. 41 is a plan view of a magnetic sensor according to a ninth embodiment of the invention.

FIG. 42 is a sectional side view of the magnetic sensor shown in FIG. 41.

FIG. 43 is a plan view of a lead frame that may be used in the manufacture of the magnetic sensor shown in FIG. 41.

FIG. 44 is a plan view illustrating the top projecting members before they are tilted in the lead frame shown in FIG. 43.

FIG. 45 is a sectional view along line I-I of the lead frame shown in FIG. 44.

FIG. 46 is a sectional view along line I-I of the lead frame shown in FIG. 43.

FIGS. 47, 48 and 49 are sectional views depicting steps in the manufacture of the magnetic sensor shown in FIG. 42.

FIG. 50 is a plan view of variations of the top projecting members and the connecting members in the lead frame shown in FIG. 43.

FIG. 51 is a sectional view along line J-J of the lead frame shown in FIG. 50.

FIG. 52 is a plan view of a variation of the connecting members in the lead frame shown in FIG. 50.

FIG. 53 is a sectional side view of variations of the top projecting members and leads in the lead frame shown in FIG. 50.

FIG. 54 is a sectional side view of the stage in the tilted state in the variation shown in FIG. 53.

FIG. 55 is a sectional side view of variations of the leads and connecting members in the lead frame shown in FIG. 52.

FIG. 56 is a sectional side view of the stage in the tilted state in the variation shown in FIG. 55.

FIG. 57 is a sectional side view of a magnetic sensor according to a tenth embodiment of the invention.

FIG. 58 is a sectional side view of a variation of the leads in the magnetic sensor shown in FIG. 57.

FIG. 59 is a plan view of a variation of the top projecting members in a lead frame that may be used in the magnetic sensor shown in FIG. 57.

FIG. 60 is a plan view of another variation of the top projecting members in a lead frame that may be used in the magnetic sensor shown in FIG. 57.

FIG. 61 is a sectional side view of a conventional magnetic sensor.

### DESCRIPTION OF THE PREFERRED EMBODIMENTS

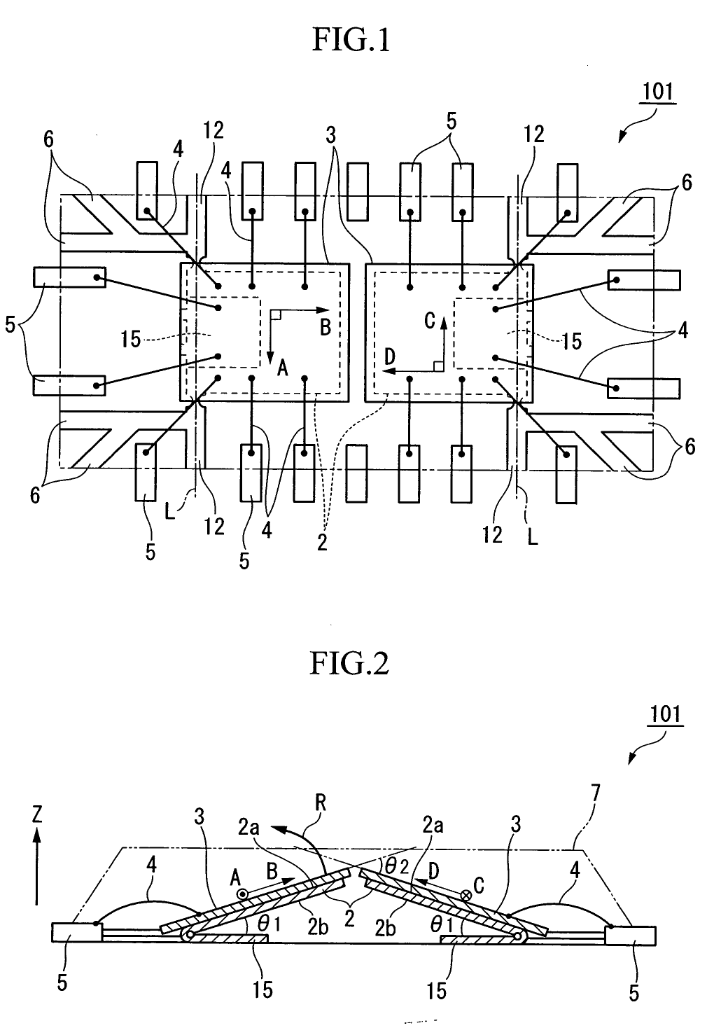

A lead frame and a physical sensor according to a first embodiment of the invention will be described below while referring to FIGS. 1 to 7. In the following description of this embodiment, the physical sensor is exemplified by a magnetic sensor for measuring three-dimensional geomagnetism.

The magnetic sensor 101 (physical sensor) in the present embodiment, as illustrated in FIGS. 1 and 2, has two stages 2 which are mutually tilted, magnetic sensor chips 3 for measuring the size and direction of an external magnetic field that are mounted on top sides 2a of these respective stages 2, leads 5 and 6 which are electrically connected with the magnetic sensor chips 3 by wires 4, and a molded resin body 7 which integrally fixes these components.

This magnetic sensor 101 is manufactured using a lead frame 10 having stages 2 and leads 5 and 6. The method of manufacture is described in detail later in the specification.

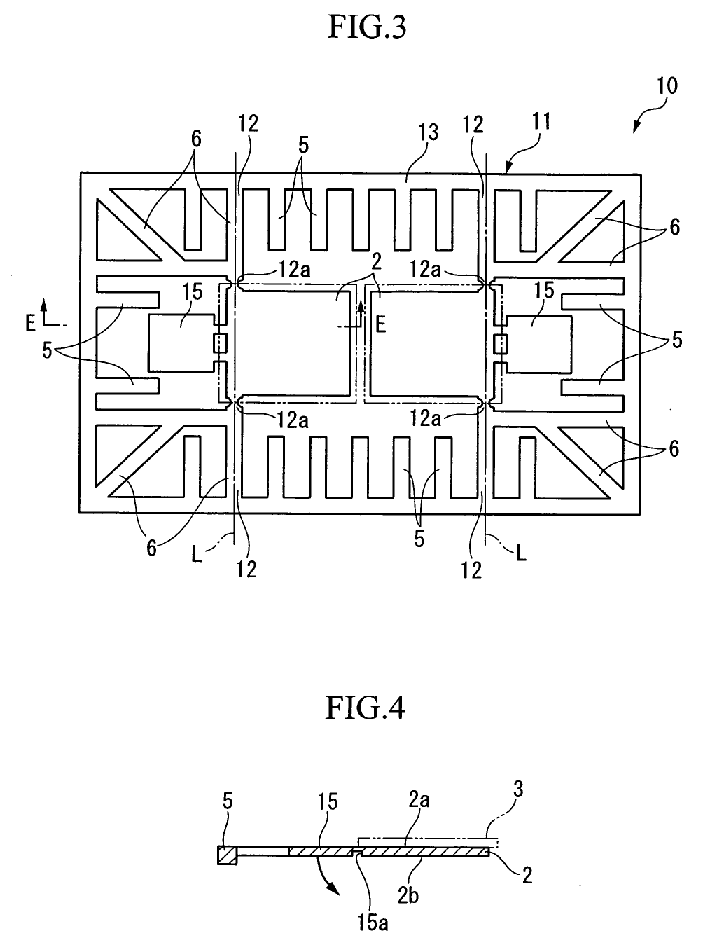

The lead frame 10 is formed by pressworking, etching or otherwise shaping thin-gauge sheet metal such as sheet copper. As shown in FIGS. 3 and 4, the lead frame 10 has two rectangularly shaped stages 2, a frame 11 with a plurality of leads 5 and 6 disposed peripherally around the stages 2, and pairs of connecting members 12 which connect the frame 11 and the stages 2 and are disposed opposite each other across the stages 2 at proximal edges of the stages 2.

The frame 11 has a border 13 provided with a shape that is rectangular, as seen in a plan view, so as to surround the stages 2, and a plurality of leads 5 and 6, respectively, which project inward from this rectangular border 13.

The leads 6 function as suspension leads for securing the stages 2 to the rectangular border 13, and are connected to the stages 2 through the pairs of connecting members 12. The pairs of connecting members 12 have recessed notches provided in the sidewalls thereof, making them narrower than other portions of the leads 5 and 6. These notches form twisting sites 12a which can readily be deformed and twisted when tilting the stages 2.

The stages 2 are arranged side-by-side in the lengthwise direction of the rectangular border 13, with the distal edges thereof mutually opposed. Each stage 2 is connected to the leads 6 through one pair of connecting members 12. The stages 2 can be deformed around an axis L that connects the pair of connecting members 12.

The stages 2 have plate-like bending members 15 connected at the proximal ends thereof. These bending members 15 are capable of being bent toward the bottom sides 2b of the stages 2 to a tilt angle θ1 therewith of 90° or less; that is, to an acute angle.

Referring to FIG. 2, it is advantageous for the above angle θ1 to be such as to result in a larger relative angle θ2 between the sensing direction B of one magnetic sensor chip 3 and the sensing direction D of the other magnetic sensor chip 3. Hence, θ1 is preferably ≧10°, more preferably ≧15°, and most preferably ≧30 to 40°.

If θ1=90°, this is desirable for lowering the price because a single magnetic sensor chip 3 will suffice for detecting magnetism in the Z direction. However, although increasing θ1 is effective for achieving a smaller package footprint, the package thickness increases. Therefore, as noted above, θ1 is most preferably ≧30 to 45°. For low-profile package applications, it is desirable for θ1 to be set to an angle of 10° to 15°.

The opposed stages 2 need not necessarily be symmetrically disposed. For example, if the conditions at the time of resin injection are non-uniform, the chip angle θ1 on the side where the resin enters first or faster will be smaller, and the angle θ1 of the other chip will be larger. That is, because the same resin injection pressure does not always apply to both stages 2 at the time of resin injection, the tilt angle θ1 by one of the stages will sometimes be larger than the other angle θ2. Moreover, if the two stages differ in size, resin injection under uniform conditions may result in a similar disparity in the angles.

Therefore, instead of precisely setting the tilt angle θ1 for each stage 2, the tilt angles of the two stages 2 may be designed based on the relative angle θ2 (θ_{BD}) therebetween. In this case, the relative angle θ2 (θ_{BD}) of each stage 2 is set at 20°≦θ_{BD}≦160°, preferably 30°≦θ_{BD}≦150°, and most preferably about 90°.

The bending members 15, as shown in FIG. 3, are formed integrally with the stages 2 in a shape that is, for example, rectangular as seen in a plan view and somewhat smaller than the stages 2. As shown in FIG. 4, the bending members 15 can be bent along one edge at the distal edge of the stages 2.

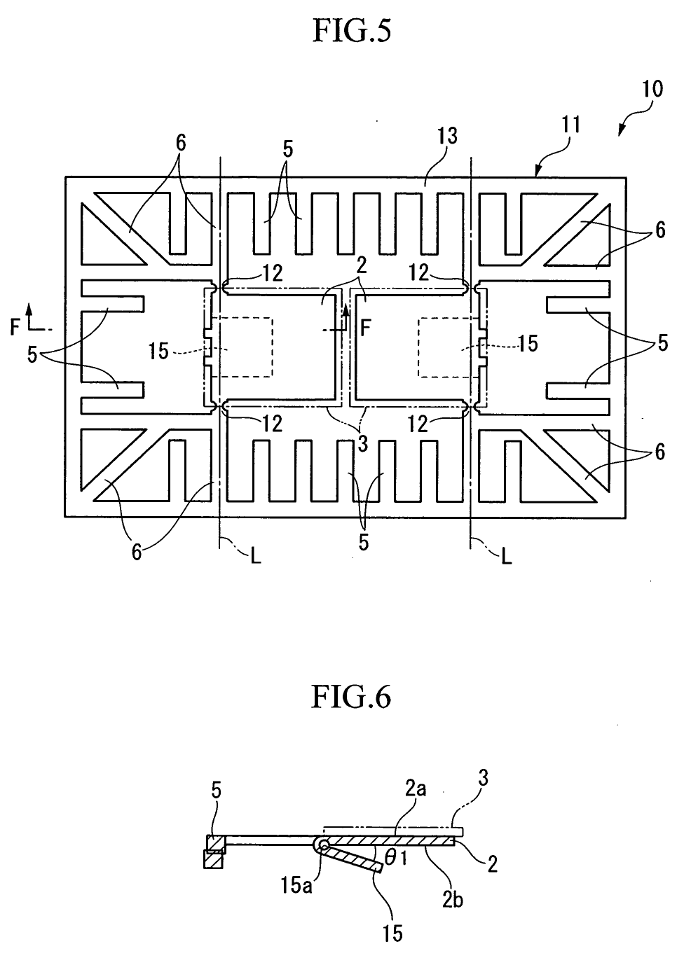

When the bending members 15 have been bent, as shown in FIGS. 5 and 6, they become positioned below the stages 2. That is, the bending members 15 become entirely covered by the bottom side of the stages and do not extend outward. This arrangement is suitable for miniaturizing the magnetic sensor 101.

As shown in FIG. 4, the bending members 15 have formed, on the bottom sides thereof near the stages 2, depressions 15a that are recessed in the thickness direction. Because the bending members 15 have a smaller sheet thickness near the stages 2 than in other portions thereof, they readily deform here, enabling the bending members 15 to be easily and reliably bent.

As shown in FIG. 1, the two magnetic sensor chips 3 mounted on the top sides 2a of the stages 2 in the lead frame 10 are both sensitive to magnetic components of the external magnetic field in two directions. The sensitive directions in one of these magnetic sensor chips 3 are mutually orthogonal directions along the surface of the magnetic sensor chip 3 (direction A and direction B), and the sensitive directions in the other magnetic sensor chip 3 are mutually orthogonal directions along the surface of that magnetic sensor chip 3 (direction C and direction D). Directions A and C are both parallel to the axis L and of opposite orientation, and directions B and D are both orthogonal to the axis L and of opposite orientation.

Alternatively, the other magnetic sensor chip 3 may be of a type having only direction D sensitivity. It is also possible for the other magnetic sensor chip 3 to be kept horizontal.

Next, a method of manufacturing the magnetic sensor 1 using the above-described lead frame 10 is described. In the lead frame 10, as shown in FIGS. 5 and 6, the bending members 15 may be in a pre-bent state.

First, the magnetic sensor chips 3 are each bonded to the top sides 2a of the stages 2. In this step, the magnetic sensor chips 3 are bonded in such a way that the sensitive directions are oriented as shown in FIG. 1.

Next, bonding pads (not shown) for the magnetic sensor chips 3 are electrically connected to the leads 5 by wires 4. This enables the magnetic sensor chips 3 and the plurality of leads 5 to be electrically connected to each other. When the stages 2 are tilted as subsequently described, the positions of the bonding areas between the magnetic sensor chips 3 and the leads 5 vary with respect to each other, so it is desirable for the wire 4 to be made of a flexible material that readily bends.

Next, a molded resin body 7 that integrally fixes the magnetic sensor chips 3, the stages 2, and the leads 5 and 6 is formed.

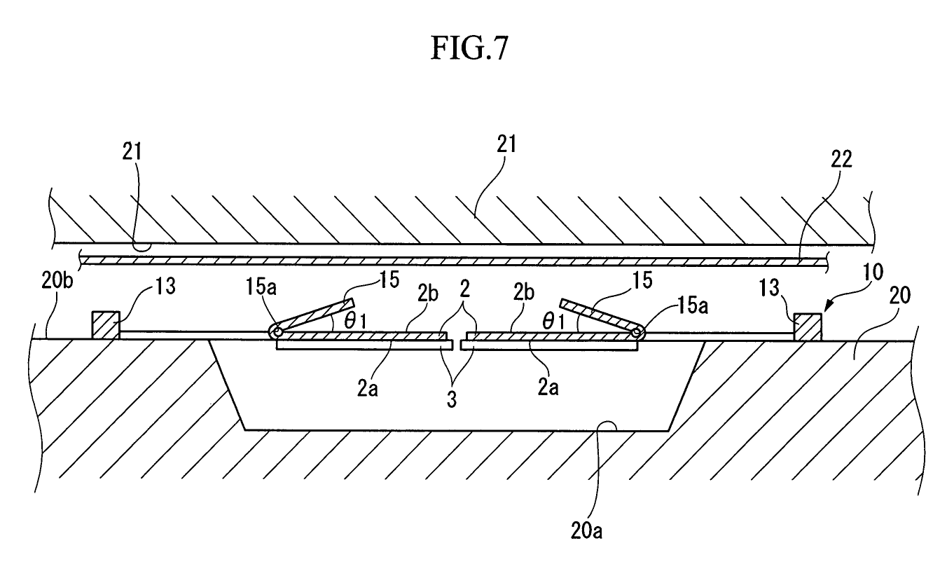

First, as shown in FIG. 7, the rectangular border 13 of the lead frame 10 is placed on the surface 20b of a first mold half 20 having a recess 20a. At this time, the leads 5 and 6, stages 2, magnetic sensor chips 3 and bending members 15 located inside the rectangular border 13 are positioned above the recess 20a. In this state, the magnetic sensor chips 3, the stages 2 and the bending members 15 are arranged in this order upward from the recess 20a side. A second mold half 21 having a flat surface 21a is disposed above the bending members 15 and, together with the first mold half 20, clamps therebetween the rectangular border 13 of the lead frame 10.

A sheet mold 22 for facilitating separation of the second mold half 21 and the subsequently described resin is disposed between the lead frame 10 and the second mold half 21.

When the lead frame 10 is clamped between the two mold halves 20 and 21, the flat surface 21a of the second mold half 21 presses against the bending members 15, causing the stages 2 to move downward in FIG. 7. Each stage 2 thus deforms so as to rotate around an axis L connecting a pair of connecting members 12.

The stages 2 thus tilted when the bending members 15 are pushed down by the flat surface 21a of the second mold half 21, with deformation coming to a stop the moment that the first mold half 20, the lead frame 10 and the second mold half 21 have been clamped together. At this time, the surfaces of the bending members 15 are substantially parallel with the top sides 2a of the stages 2 prior to rotation. Moreover, the above-described acute angle when the bending members 15 were bent is retained as the angle θ1 between the bending members 15 and the stages 2.

A molten resin is then injected into both mold halves 20 and 21, thereby forming a molded resin body 7 within which are embedded the magnetic sensor chips 3. The magnetic sensor chips 3 are thus fixed at the interior of the molded resin body 7 in a mutually tilted state. To keep the tilt angle of the magnetic sensor chips 3 and the stages 2 from changing due to resin flow, it is preferable for this resin to be a material having a high fluidity.

Finally, the rectangular border 13 that extends outside of the molded resin body 7 is trimmed off, which individually separates each of the leads 5 and 6. The two mold halves 20 and 21 are then removed, thereby completing the magnetic sensor 101 shown in FIGS. 1 and 2.

During formation of the molded resin body 7 after the lead frame 10 has been clamped between the two mold halves 20 and 21, the bending members 15, having been formed by being bent at the proximal edges of the stages, have a tendency to return to their original state on account of elastic recovery. However, because the bending members 15 are in contact with the flat surface 21a of the first mold half 20, elastic deformation does not occur. Instead, this force of elastic deformation acts upon the stages 2, causing the stages 2 to try returning to their original positions (in the direction of arrow R in FIG. 2). Hence, the stages 2 try rotating further around the axis L in a direction that increases the angle θ1 between the stages 2 and the bending members 15, facilitating rotation of the stages 2 in a direction that increases the tilt angle.

In this way, before the resin sets, the stages 2 try to deform to a tilt angle which is deeper (larger), rather than shallower (smaller) as in the prior art. Therefore, the angle θ2 between the top sides 2a of the two stages 2, i.e., the angle θ2 between the A-B plane and the C-D plane, readily changes so as to become larger. As a result, a decrease in the detection sensitivity by the magnetic sensor chip 3 in the Z direction (thickness direction) can be prevented.

This angle θ2 is preferably at least 20°, and more preferably at least 30°.

The back sides of the plurality of leads 5 that are electrically connected to the magnetic sensor chips 3 by the wires 4 are exposed on the bottom side of the molded resin body 7. As a result, heat generated by the magnetic sensor chips 3 is easily dissipated through the stages 2 and the bending members 15 (projecting members), which can be expected to reduce measurement error associated with the temperature of the magnetic sensor chips 3.

These magnetic sensors 101 are placed on a substrate within a handheld device such as a cellular phone and are electrically connected to the back sides of the leads 5. The magnetic sensor chips 3 can detect the geomagnetic direction as a vector in three-dimensional space, and can display the measured geomagnetic azimuth to, for example, a display panel (not shown). In this way, a handheld device can be provided with a variety of navigation functions that utilize geomagnetism.

In particular, because, as described above, the detection sensitivity by the magnetic sensor chips 3 in the Z direction (thickness direction) does not decrease, the magnetic sensor 101 can detect geomagnetism to a high accuracy in all directions in three-dimension space. The reliability and added value of the navigation functions in the handheld device are thus enhanced.

As noted above, when the lead frame 10 of this embodiment is used, the stages 2 readily deform in a direction that increases the angle θ1 with the bending members 15, that is, in a direction that increases the tilt angle of the stages 2, thus enabling a decline in the sensitivity of detection by the magnetic sensor chips 3 in the Z direction (thickness direction) to be prevented. Moreover, by using the above-described lead frame 10 to manufacture the magnetic sensor 101 of this embodiment, geomagnetism can be detected to a high accuracy in all directions in three-dimension space.

In addition, because the bending members 15 can be bent downward from one edge of the respective stages 2, the bending members 15 are positioned on the bottom side of the stages 2 without extending outside of the regions occupied by the stages 2 as viewed from the top surface thereof. Therefore, as shown in FIGS. 1 and 2, the two stages 2 can be brought into very close proximity, which is conducive to miniaturization of the sensor. Also, each bending member 15 can be easily and reliably bent by means of recesses 15a formed on the bottom side thereof near the corresponding stage 2, thus making it easy to deform the stage 2 to a desired tilt angle. Moreover, the surface of the bending member 15 is exposed on the bottom side of the molded resin body 7, facilitating heat dissipation.

The technical scope of the present invention is not limited by the foregoing embodiment, which can be variously modified and altered without departing from the gist of the invention.

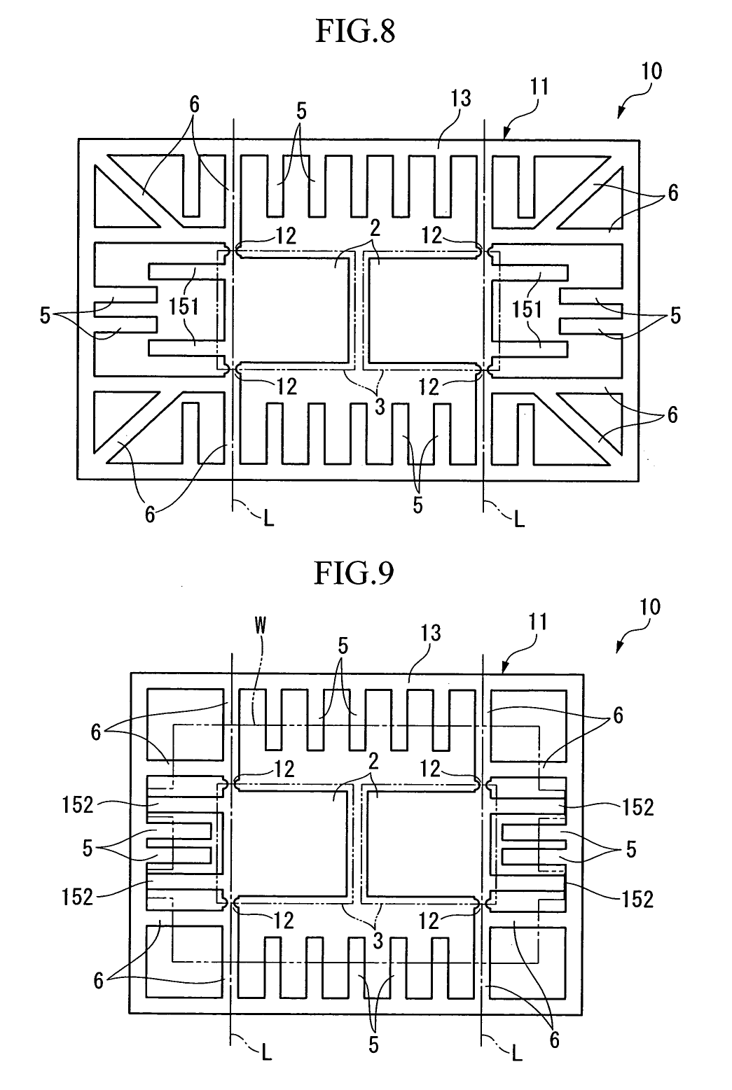

For example, in the above-described embodiment, the bending members 15 were given a rectangular shape that is somewhat smaller than the stages 2. However, the bending members 15 are not limited to this shape. As shown in FIG. 8, the bending members 151 may be given the same shape as the leads 5, and a plurality (two) of such members 151 may be formed for each stage 2. By forming the bending members 151 so that they have the same shape as the leads 5 and so that the leads 5 and the bending members 151 mutually bypass, the number of leads 5 can be increased and space is effectively used, enabling miniaturization to be achieved.

Moreover, by forming a plurality of bending members 151 per stage 2, the stages 2 can be more stably raised and supported, making it easy to more reliably set the stages to a desired angle. In addition, because the bending members 151 can be given the same small shape as the leads 5, the exposed surface area on the bottom side of the molded resin body 7 can be decreased. It is thus possible reduce the influence upon the substrate on which the sensor is mounted.

Also, as shown in FIG. 9, by utilizing at this time up to a region W where the leads 5 are finally cut to form bending members 152, even further miniaturization can be achieved.

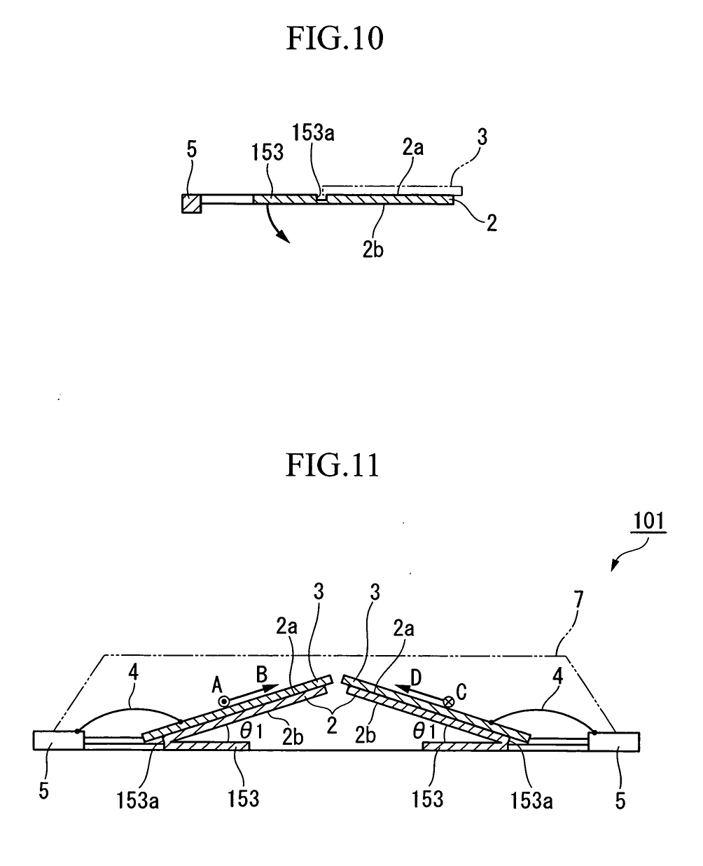

In the above-described embodiment, a recess 15a was formed on the bottom side of each bending member 15. However, as shown in FIGS. 10 and 11, a recess 153a can just as well be formed on the top side of the bending member 153 by a suitable process such as half-etching or pressworking. In this case, the bending surface is flat, resulting in little resin flash and better adhesion with the magnetic sensor chip 3.

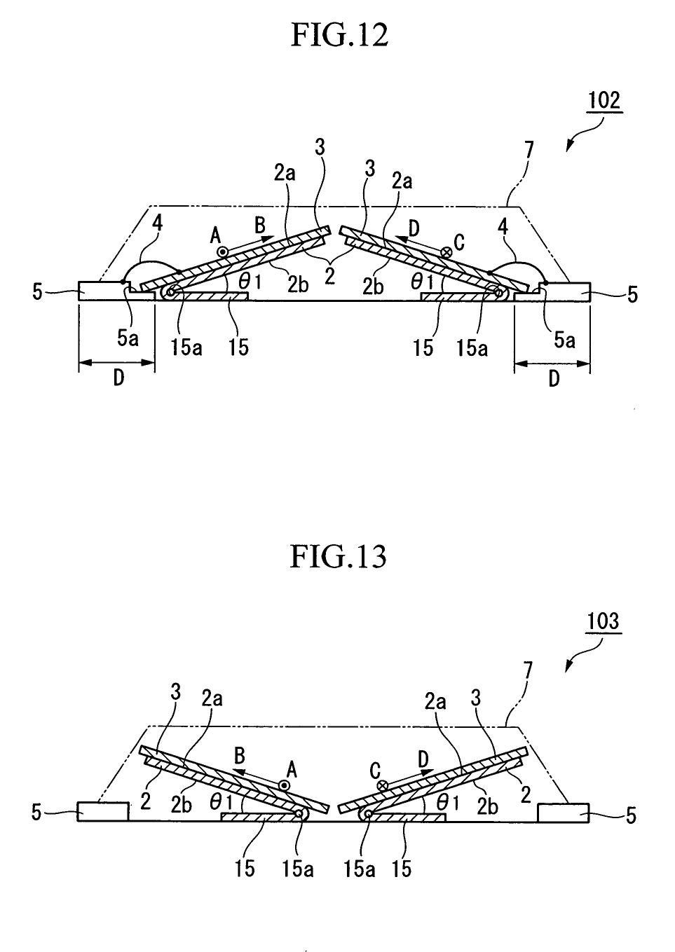

In the magnetic sensor 102 shown in FIG. 12, the magnetic sensor chips 3 are positioned (stacked) on outer leads 5. This enables the entire sensor 102 to be further miniaturized. In addition, at this time, notches 5a may be formed in portions of the outer leads 5 such as by half-etching. In this way, interference with the magnetic sensor chips 3 can be prevented, enabling even further miniaturization to be achieved. Instead of just forming notches 5a, it is even more preferable to first shorten the half-etching width D in a region close to the magnetic sensor chips 3.

In the above first and second embodiments, the two stages 2 are oppositely disposed so that their respective distal edges are in close proximity, although the invention is not limited to such an arrangement. For example, the two stages 2 may be oppositely disposed so that their respective proximal edges are in close proximity, in the manner of the magnetic sensor 103 shown in FIG. 13. In this way, even if the leads 5 are brought closer to the stages 2, interference (contact) between the stages 2 and the leads 5 can be prevented, making even further miniaturization possible.

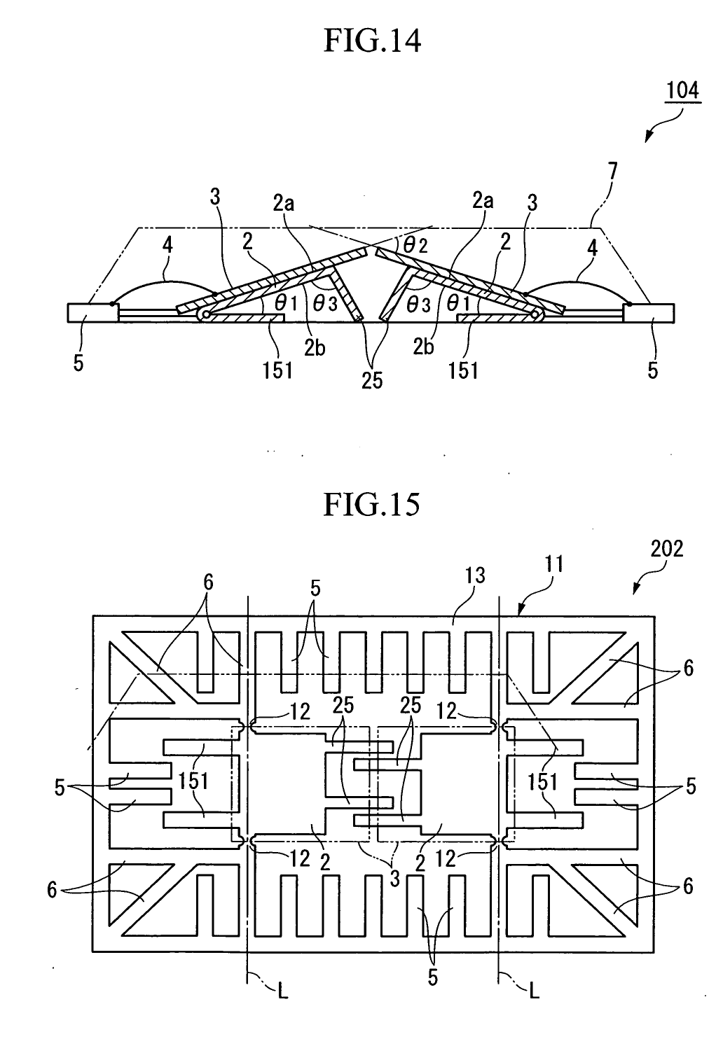

Furthermore, as illustrated by the magnetic sensor 104 shown in FIGS. 14 and 15, there may be formed projecting members 25 which project out from the distal edge of each stage 2 in a lead frame 202 and on the bottom side of the stage 2 so as to form an angle θ3 with the bottom side 2b of the stage 2 which is maintained at an angle larger than 90°. The projecting members 25 are formed by first pressworking or otherwise shaping the sheet metal in the same way as is done for the bending members 151, followed by bending so that the angle θ3 with the bottom side 2b of the stage 2 is held at an angle greater than 90°.

Providing these projections members 25 enables the tilted stages 2 to be more reliably supported and also prevents the stages 2 from rising upward. By forming in particular a plurality of (two) projecting members 25, reliable support is assured. Because the projecting members 25 are provided at distal edges of the stages 2, support can be effectively carried out.

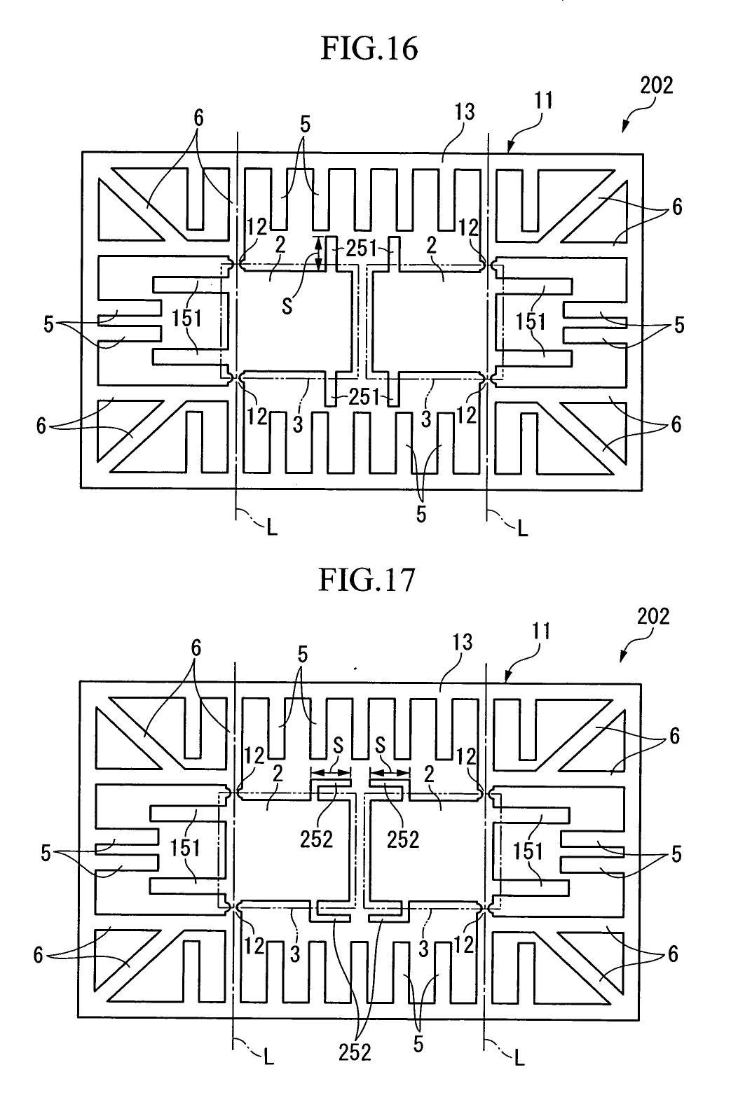

As shown in FIG. 16, additional projecting members 251 may also be provided on both lateral edges of the stages 2. This allows the two stages to be brought into close proximity, enabling sensor miniaturization to be achieved.

Alternatively, as shown in FIG. 17, L-shaped projecting members 252 may be provided on both lateral edges of the stages 2, thus enabling the length S of the projecting members 25 to be increased. That is, by bending the projecting members 252 so that they change direction 90° at some intermediate point along their length and extend in the lengthwise direction of the rectangular border 13, the distance between both lateral edges of the stages and the leads 5 can be reduced, enabling further miniaturization to be achieved.

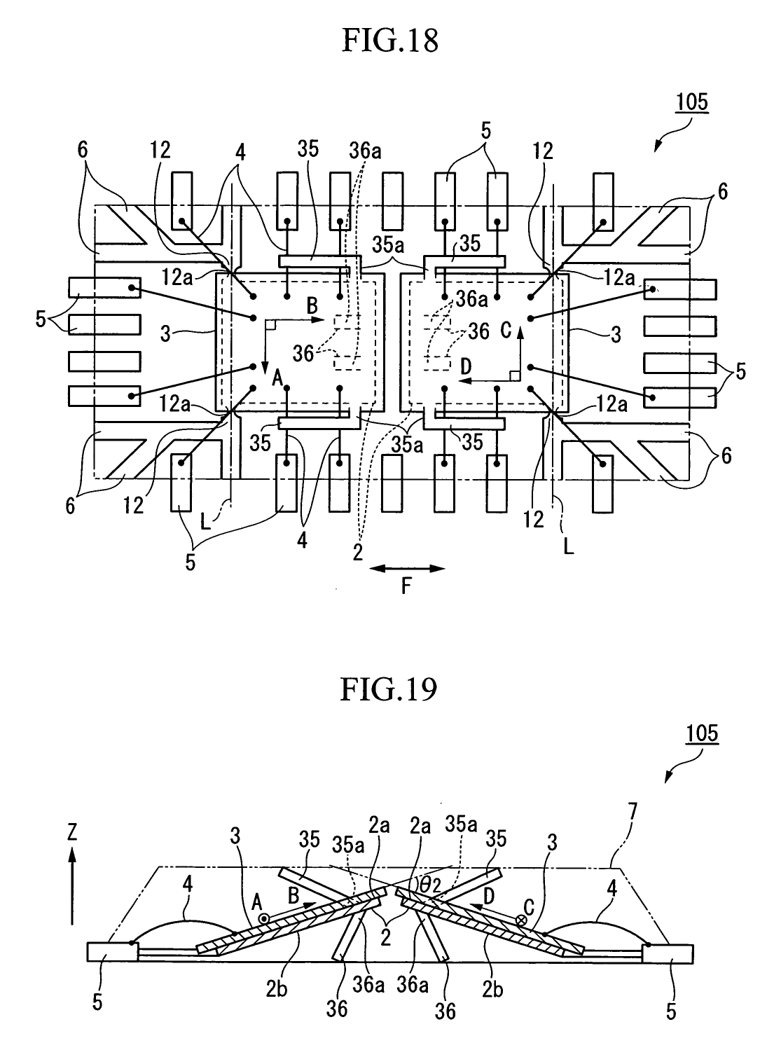

Next, a lead frame and a physical sensor according to a fifth embodiment of the invention will be described while referring to FIGS. 18 to 21. Features similar to those in the embodiments described above are labeled with the same reference numbers, and repetitions of the same explanations are omitted.

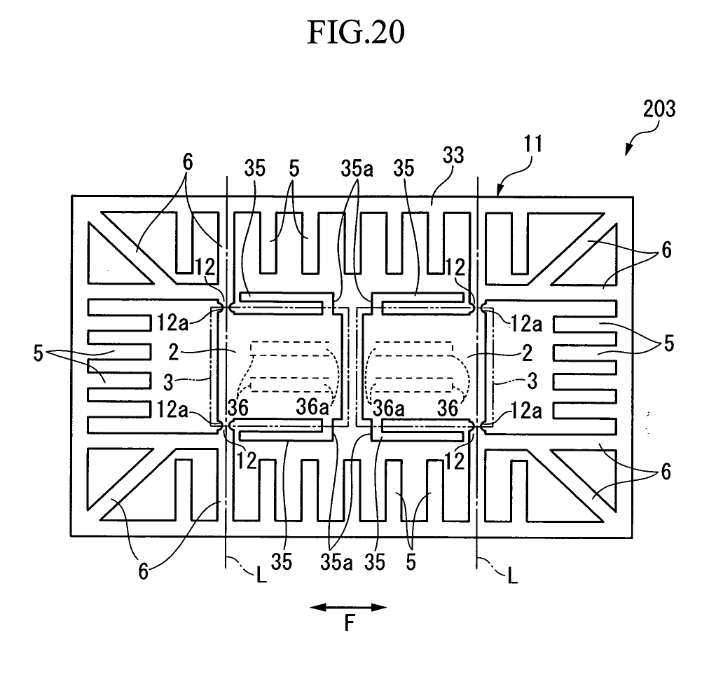

The magnetic sensor 105 in the embodiment shown in FIGS. 18 and 19 is manufactured using the lead frame 203 shown in FIG. 20. In this embodiment, to further stabilize the tilt by the stages 2, in addition to the arrangement in the first embodiment, top projecting members 35 are provided on the stages 2.

That is, the stages 2 have, tilted at acute angles thereto, top projecting members 35 which project out on the top side 2a of the stage 2 and bottom bending members 36 which project out on the bottom side of the stage 2. FIG. 20 shows the top projecting members 35 and the bottom bending members 36 in their unbent states.

The pair of connecting members 12 provided in the lead frame 203 have twisting portions (deforming portions) which deform more easily than the top projecting members 35 and the bottom bending members 36.

Two top projecting members 35 are formed, each having a proximal end 35a positioned at the distal edge of the stage 2 and extending in an L-shape, as seen in a top plan view, along the lengthwise L direction on either lateral edge of the stage.

Two (multiple) bottom bending members 36, each having a proximal end 36a positioned at the distal edge of the stage 2, are formed along the lengthwise L direction in such a way as to cut out portions of the stage 2. These top projecting members 35 and bottom bending members 36 are bent and thereby tilted as shown in FIG. 19.

Next, a process for manufacturing the magnetic sensor 105 by using the above-described lead frame 203 will be described. It should be noted here that the top projecting members 35 and the bottom bending members 36 are bent beforehand from the lead frame 203 as shown in FIGS. 18 and 19.

First, magnetic sensor chips 3 are bonded to the top sides 2a of each stage 2. Bonding pads (not shown) for the magnetic sensor chips 3 are then electrically connected by wires 4 to the leads 5 and 6.

Next, a molded resin body 7 which integrally fixes the magnetic sensor chips 3, the stages 2 and the leads 5 and 6 is formed.

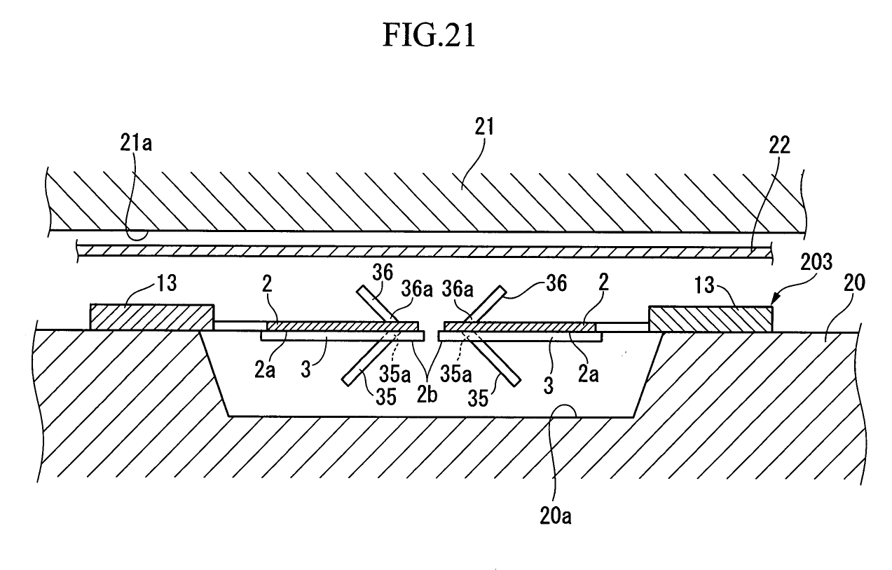

As shown in FIG. 21, the rectangular border 13 of the lead frame 203 is mounted on the surface of a first mold half 20 having a recess 20a. At this time, the leads 5 and 6, stages 2, magnetic sensor chips 3, top projecting members 35 and bottom bending members 36 are positioned above the recess 20a. The top projecting members 35, magnetic sensor chips 3, stages 2, and bottom bending members 36 are disposed in this order from the side of the recess 20a upward. A second mold half 21 having a flat surface 21a is positioned above the bottom bending members 36 and, together with the first mold half 20, clamps therebetween the rectangular border 13 of the lead frame 203.

When the lead frame 203 is clamped between both mold halves 20 and 21, the flat surface 21a of the second mold half 21 pushes against the bottom bending members 36, causing them to move downward in FIG. 21. This causes the stages 2 to deform by rotating about the axes L connecting pairs of connecting members 12 so that the distal edges of the stages 2 begin tilting toward the first mold half 20. Because the pairs of connecting members 12 have deforming portions 12a formed thereon, the stages 2 easily rotate about the axes L. Moreover, as the stages 2 rotate, the distal ends of the top projecting members 35 approach the surface of the recess 20a in the first mold half 20.

The stages 2 tilt because the bottom bending members 36 are pushed downward by the flat surface 21a of the second mold half 21. Deformation of the stages 2 stops when the first mold half 20, the lead frame 203 and the second mold half 21 have become clamped together.

At this time, the top projecting members 35, because the distal ends thereof come into contact with the surface of the recess 20a, act to push up (upwards in FIG. 21) the stages 2. The stages 2 thus tilt while being held from above and below between the top projecting members 35 and the bottom bending members 36, and so the tilted state is stable.

Moreover, when the top projecting members 35 and the bottom bending members 36 are elastically deformed, the stages 2 can be fixed in a position where the vertical deformation stresses are in balance. In particular, when packaging is carried out by resin encapsulation, because the resin hardens with these members in a deformed state, even plastic deformation suffices.

Resin is injected into both mold halves 20 and 21 in this state, thereby forming a molded resin body 7 that embeds the magnetic sensor chips 3 within the resin. As a result, the magnetic sensor chips 3 are fixed at the interior of the molded resin body 7 in a mutually tilted state. Finally, the rectangular border 13 that protrudes outside of the molded resin body 7 is trimmed off so as to individually cut apart each of the leads 5 and 6, following which the two mold halves 20 and 21 are removed. This completes production of the magnetic sensor 105 shown in FIGS. 18 and 19.

As noted above, the stages 2 are held from above and below by the top projecting members 35 and the bottom bending members 36 before the resin hardens, thereby stabilizing the tilted state. Moreover, the tilt angle can easily be adjusted to the desired angle by adjusting the length of the top projecting members 35 and the bottom bending members 36, thus making it thus possible to enhance the tilting precision. In addition, the stages 2 can be prevented from rising upward, enabling the detection sensitivity by the magnetic sensor chips 3 in the Z direction (thickness direction) to be enhanced.

As shown in FIG. 19, the angle θ1 formed between the two stages 2 is preferably at least 20°, and more preferably at least 30°.

With the above-described lead frame 203 according to the present embodiment, the stages can easily be adjusted to the desired tilt angle by means of the top projecting members 35 and the bottom bending members 36, thus making it possible to improve the tilting precision and ensure a stable tilted state. Also, the stages 2 are held from above and below, and can thus be prevented from rising upward. In particular, because a plurality of both the top projecting members 35 and the bottom bending members 36 are formed, the stages 2 are more stably supported and can be reliably set at the desired tilt angle.

The magnetic sensor 105 of the present embodiment, because it is manufactured using the above-described lead frame 20, can detect geomagnetism to a high precision in all directions in three-dimensional space.

The technical scope of the present invention is not limited by the foregoing embodiment, which can be variously modified and altered without departing from the gist of the invention.

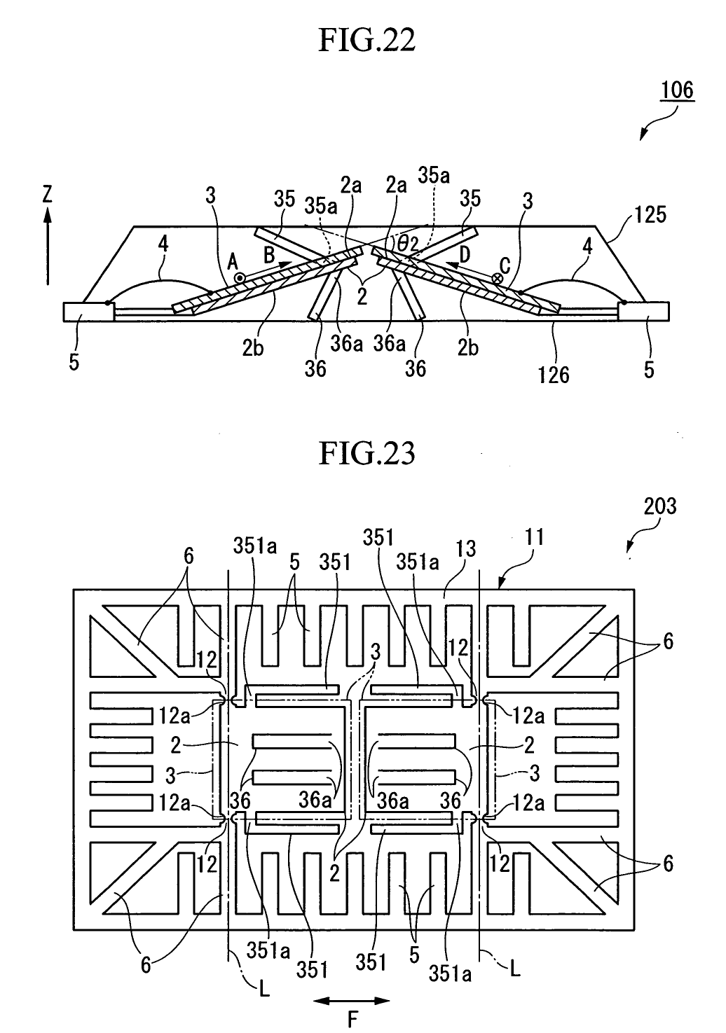

For example, in the foregoing fifth embodiment, the magnetic sensor 105 was manufactured by fixing the lead frame 203 with a molded resin body 7. However, as shown in FIG. 22, it is also possible to fix the lead frame 203 by clamping it with top and bottom lid-like exterior wall members capable of forming a space of the same shape as the mold cavity, i.e., a top outside wall member 125 and a bottom outside wall member 126, so that these come into contact with the top projecting members 35 and the bottom bending members 36.

The top wall member 125 and bottom wall member 126 are made of a suitable material such as metal, ceramic or plastic.

By using both wall members 125 and 126 to position the top projecting members 35 and the bottom bending members 36, the stages 2 can be fixed in a state that reliably maintains the desired tilt. That is, the magnetic sensor chips 3 can be fixed relative to each other in a mutually tilted state within the space enclosed between the two wall members 25 and 26.

Hence, the magnetic sensor 106 according to this sixth embodiment has a high detection sensitivity in the Z direction and can measure magnetism to a high precision in all directions in three-dimensional space.

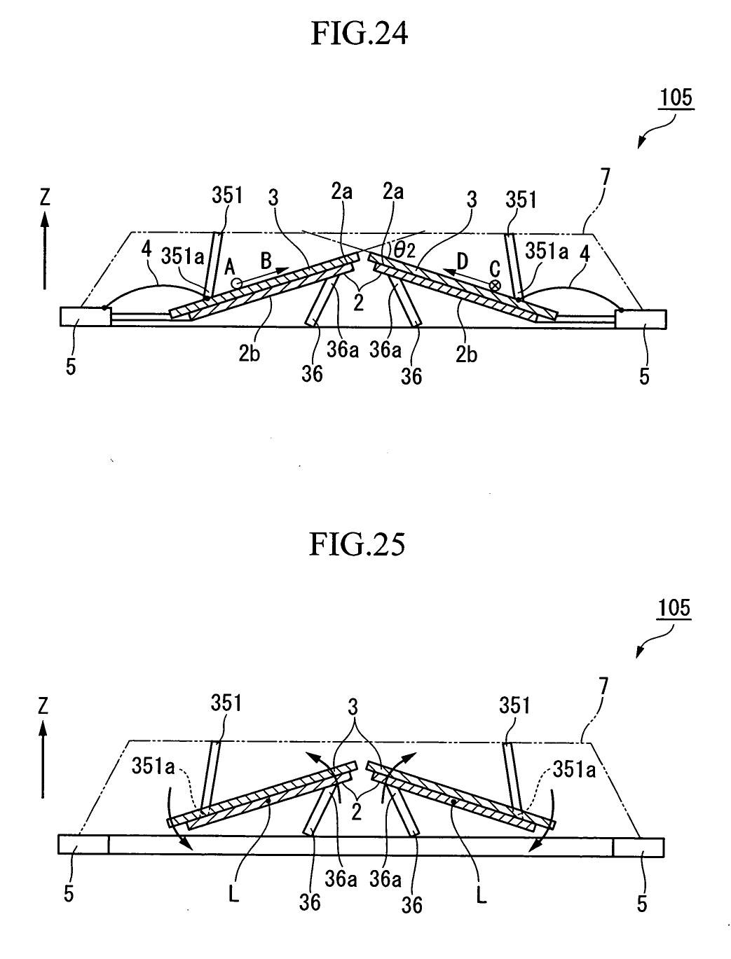

Also, in the above-described fifth embodiment, the top projecting members 35 are provided in such a way that the proximal ends 35a thereof are positioned at the distal edges of the stages 2, although the invention is not limited to such an arrangement. For example, as shown in FIG. 23, the top projecting members 351 may instead be provided at the proximal edges of the stages 2. As shown in FIG. 24, a magnetic sensor 105 manufactured using a lead frame 203 having such a construction is supported in a state where it is held between the top projecting members 351 and the bottom bending members 36 at the distal and proximal edges of the stages 2, thus making it possible to further stabilize the tilted state.

Also, as shown in FIG. 25, the connecting members 12 may be configured so as to support the stages 2 at the approximate centers L of the respective stages 2. That is, the top projecting members 351 and the bottom bending members 36 for each stage 2 may be provided so that the axis L is situated between their respective proximal ends 351a and 36a. In this case, the stages 2 are formed so as to be offset on the top side (Z direction side).

With this arrangement, when the lead frame 203 is clamped from above and below by the mold halves 20 and 21, the stages 2 can both be pushed upward at the distal edges thereof by the bottom bending members 36 and pushed downward at the proximal edges thereof by the top projecting members 351. Each stage 2 thus deforms by rotating more smoothly around the axis L and also tilts to the desired angle with higher precision, making fabrication even easier.

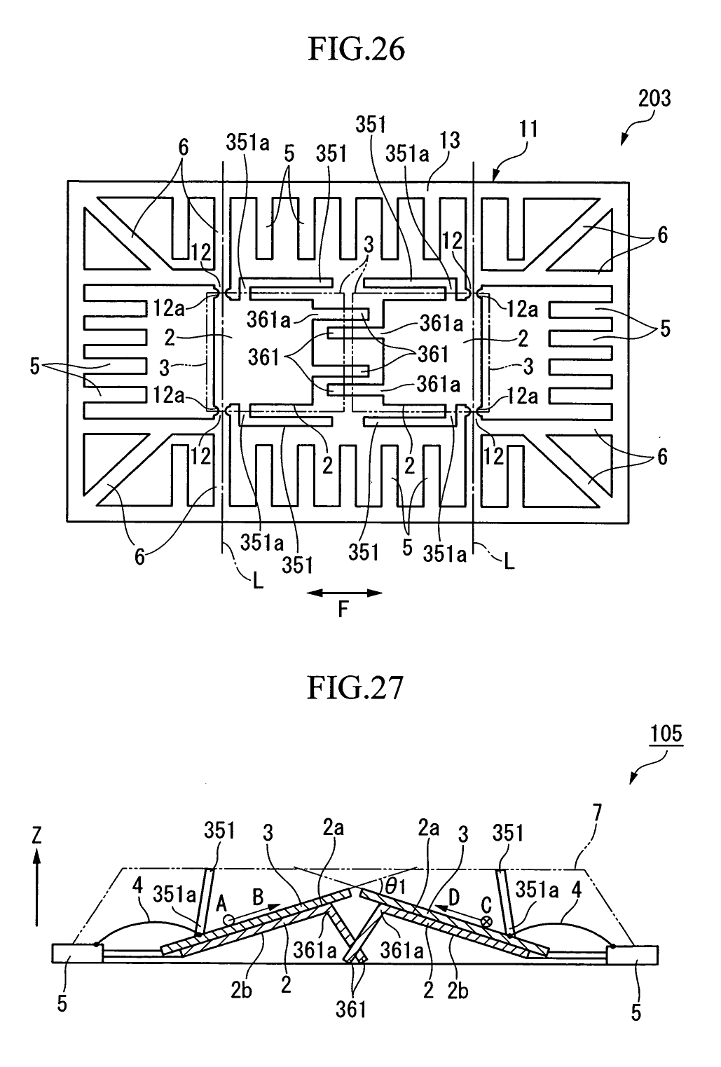

Furthermore, as shown in FIG. 26, bottom projecting members 361 may be formed so as to extend outward from the distal edges of the stages 2. As shown in FIG. 27, in a magnetic sensor 105 that has been fabricated using a lead frame 203 constructed in this way, the stages 2 are more effectively supported by the bottom projecting members 361, resulting in a more stable tilted state.

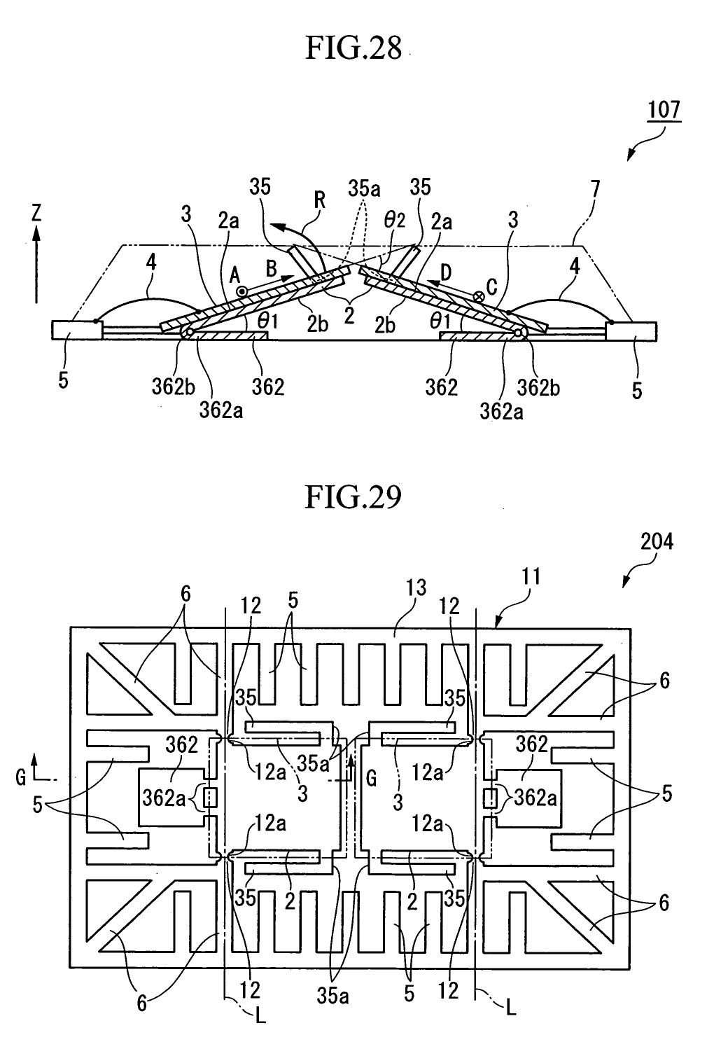

Also, as shown in FIGS. 28 to 32, the bottom bending members 362 can be formed in such a way as to bend on the bottom sides 2b of the stages 2 at the proximal edges of the stages 2 so that the angle θ1 formed thereby with the bottom sides 2b of the stages 2 is 90° or less.

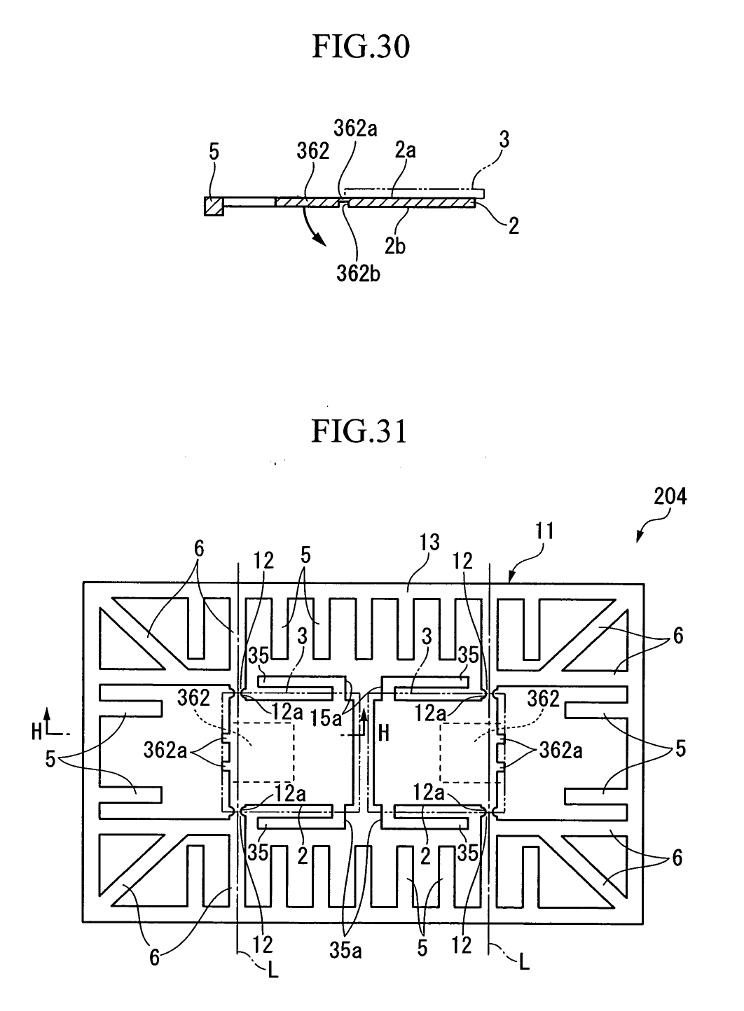

That is, as shown in FIG. 29, the bottom bending members 362 can be formed integrally with the stages 2 in a shape that is rectangular as seen in a plan view and is somewhat smaller than the stages 2 and, as shown in FIG. 30, can be bent along the proximal edge of each respective stage 2.

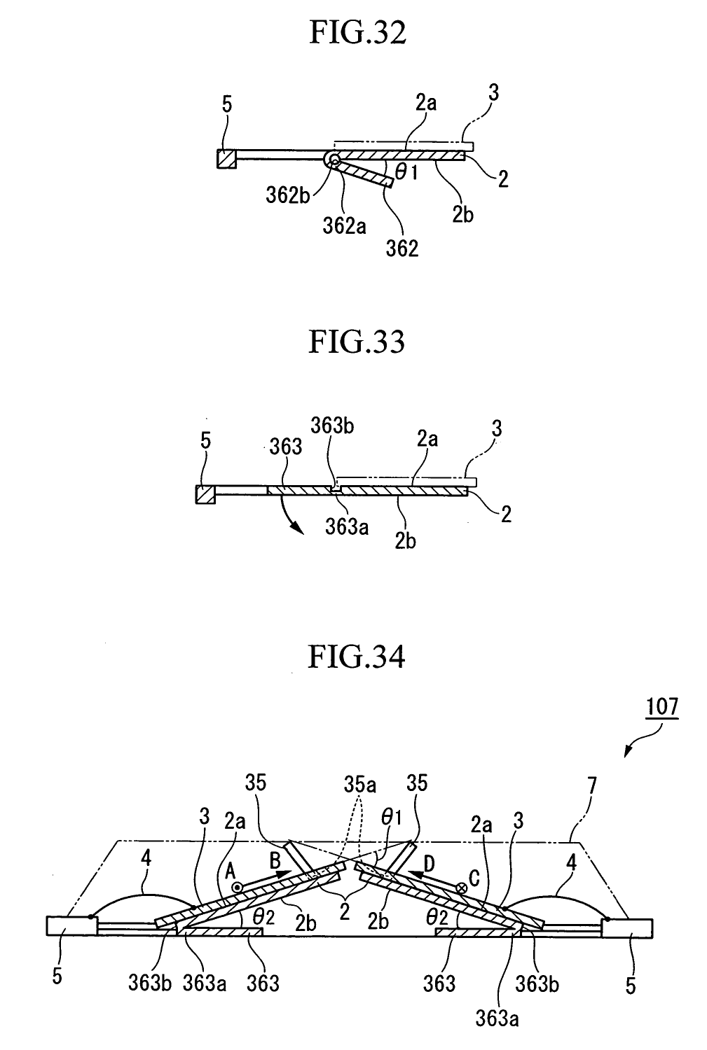

The bottom bending members 362, when bent, are positioned below the stages 2, as shown in FIGS. 31 and 32. That is, the bottom bending members 362 are disposed inside of, and do not extend outside of, regions occupied by the bottom faces 2b of the respective stages 2. This arrangement is thus desirable for miniaturizing the magnetic sensor 107.

As shown in FIGS. 30 and 32, each bottom bending member 362 has, formed on the bottom side thereof near the stage 2, recesses 362b which are hollow in the thickness direction. The bottom bending members 362 thus have a lower sheet thickness and deform more readily near the stages 2 than in other places, enabling them to bend easily and reliably.

In the manufacture of the magnetic sensor 107 shown in FIG. 28 using a lead frame 204 constructed in this way, when the lead frame 204 is clamped between the two mold halves 20 and 21, the bottom bending members 362 become substantially parallel to the top sides 2a of the stages 2 prior to tilting and the angle θ1 between the bottom bending members 362 and the stages 2 remains the same acute angle that was formed when the bottom bending members 362 were bent.

The bottom bending members 362 have been formed by being bent at the proximal edges of the stages 2, and try to return to their original state by elastic recovery. However, because the bottom bending members 362 are in contact with the flat surface 21a of the first mold half 20, they do not elastically deform. The elastic deformation forces instead act upon the stages 2, urging the stages 2 to return to their original positions (in the direction of arrow R in FIG. 28). As a result, the stages 2 attempt to rotate further about the axis L in the direction of a larger angle θ1. That is, deformation is facilitated in the direction of a larger tilt angle by the stages 2.

Therefore, before the resin hardens, the stages 2 try to deform in the direction of a larger tilt angle. The relative angle θ2 between the top sides 2a of both stages 2, i.e., the relative angle θ2 between the A-B plane and the C-D plane, thus changes readily in the direction of a larger angle. This enables a decline in the sensitivity of detection by the magnetic sensor chips 3 in the Z direction (thickness direction) to be prevented.

The angle θ2 formed by these two tilted planes is in a range of 0 to 90°, preferably at least 20°, and more preferably at least 30°. The reason is that, as the angle θ2 becomes larger, the detection sensitivity in the Z direction (due to separation from the X and Y axes) increases.

Also, because the surfaces of the bottom bending members 362 become exposed on the bottom side of the molded resin body 7, heat generated by the magnetic sensor chips 3 is more effectively dissipated, enabling a decrease in measurement error due to temperature.

As shown in FIGS. 33 and 34, recesses 363b in the bottom bending members 363 may be formed on the top side of the bottom bending members 363. The recesses 363b are typically formed by an operation such as half etching or pressworking. In this arrangement, the surface to be bent is flat, resulting in little resin flash and better adhesion with the magnetic sensor chip 3.

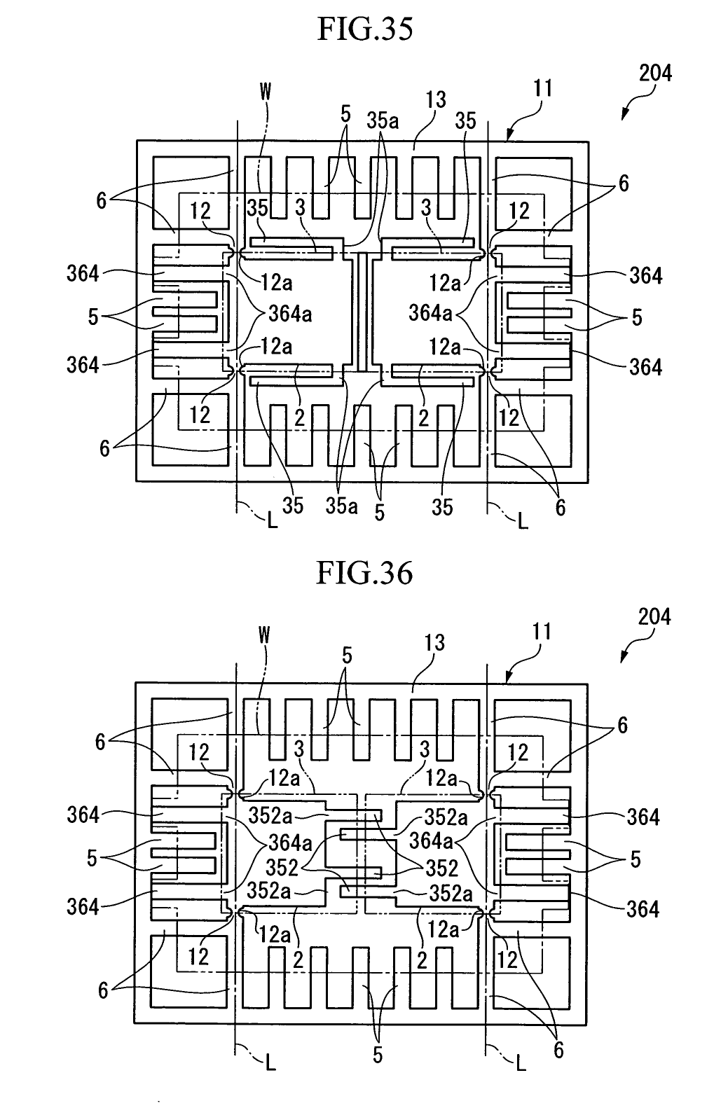

In the lead frames 204 shown in FIGS. 29 to 34, the bottom bending members 362 and 363 have been given rectangular shapes somewhat smaller than the stages 2. However, the bottom bending members are not limited to this shape. For example, as shown in FIG. 35, the bottom bending members 364 may be given the same shape as the leads 5 and a plurality of (two) such members 364 may be formed for each stage 2. By forming the bottom bending members 364 so that they have the same shape as the leads 5 and so that the leads 5 and the bottom bending members 364 mutually bypass, the number of leads 5 can be increased and space is effectively used, enabling miniaturization to be achieved.

Moreover, by forming a plurality of bottom bending members 364 per stage 2, the stages 2 can be more stably raised and supported, making it easy to more reliably set the stages to the desired angle. In addition, because the bottom bending members 364 can be given the same small shape as the leads 5, the exposed surface area on the bottom side of the molded resin body 7 can be made smaller. Hence, the influence upon the substrate on which the package is mounted can be reduced.

By utilizing up to region W where the outer leads 5 are ultimately cut to form the bottom bending members 364, even further miniaturization can be achieved.

As shown in FIG. 36, two (multiple) top projecting members 352 having proximal ends 352a provided at distal edges of the respective stages 2 may be formed so as to extend outward.

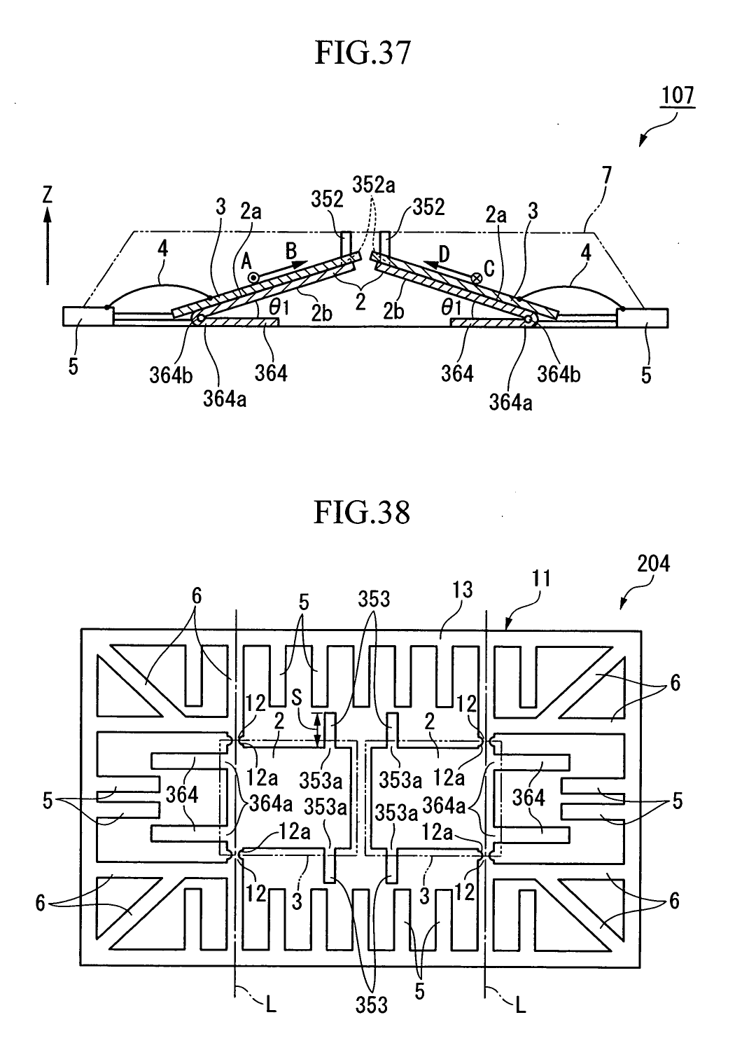

In this case, as shown in FIG. 37, it is desirable for the top projecting members 352 to be adjusted so as to face in the Z direction when the stages 2 are tilted. This makes it possible to reliably hold down the stages 2 and effectively prevents the stages 2 from rising upward.

Moreover, because the distance from the top side is accurately maintained by the length of the top projecting members 352, the thickness of the magnetic sensor 107 can be set to the design thickness even when the package has a low profile.

As shown in FIG. 38, it is also possible to provide top projecting members 353 on both lateral edges of the stages 2. Because this arrangement enables the two stages 2 to be brought into close proximity, miniaturization can be achieved.

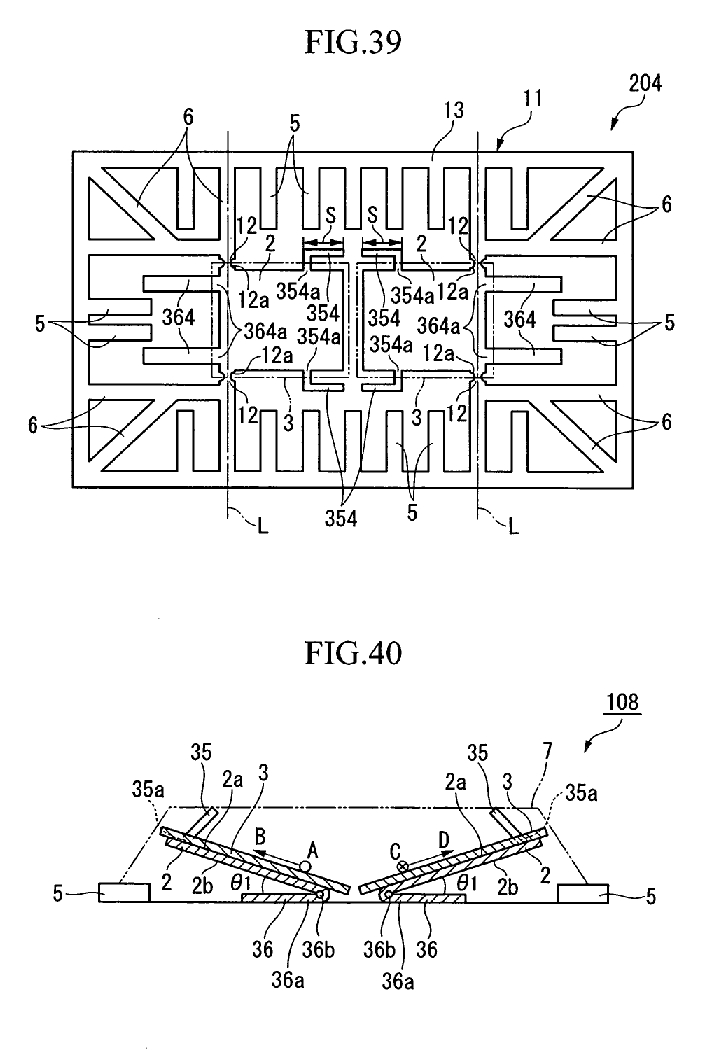

As shown in FIG. 39, L-shaped top projecting members 354 may be provided on both lateral edges of the stages 2. Such an arrangement enables the length S of the top projecting members 354 to be increased. By bending the top projecting members 354 so that they change direction 90° at some intermediate point along their length and extend in the lengthwise direction of the rectangular border 13, the distance between both lateral edges of the stages 2 and the leads 5 can be reduced, enabling the sensor to be further miniaturized.

In the above-described embodiment, the two stages 2 are oppositely disposed so that their respective distal edges are in close proximity, although the invention is not limited to such an arrangement. For example, as shown in FIG. 40, the two stages 2 may be oppositely disposed so that their respective proximal edges are in close proximity. In this arrangement, even if the leads 5 are brought closer to the stages 2, interference (contact) between the stages 2 and the leads 5 can be prevented, making even further miniaturization possible.

In the above embodiments, the magnetic sensor chips 3 have been installed on the top sides 2a of the stages 2, but are not limited to such an arrangement and may instead be installed on the bottom sides 2b of the stages 2.

Next, a lead frame and a physical sensor according to a ninth embodiment of the invention will be described while referring to the drawings. In this embodiment, a three-dimensional magnetic sensor which measures geomagnetism is described as an example of the physical sensor.

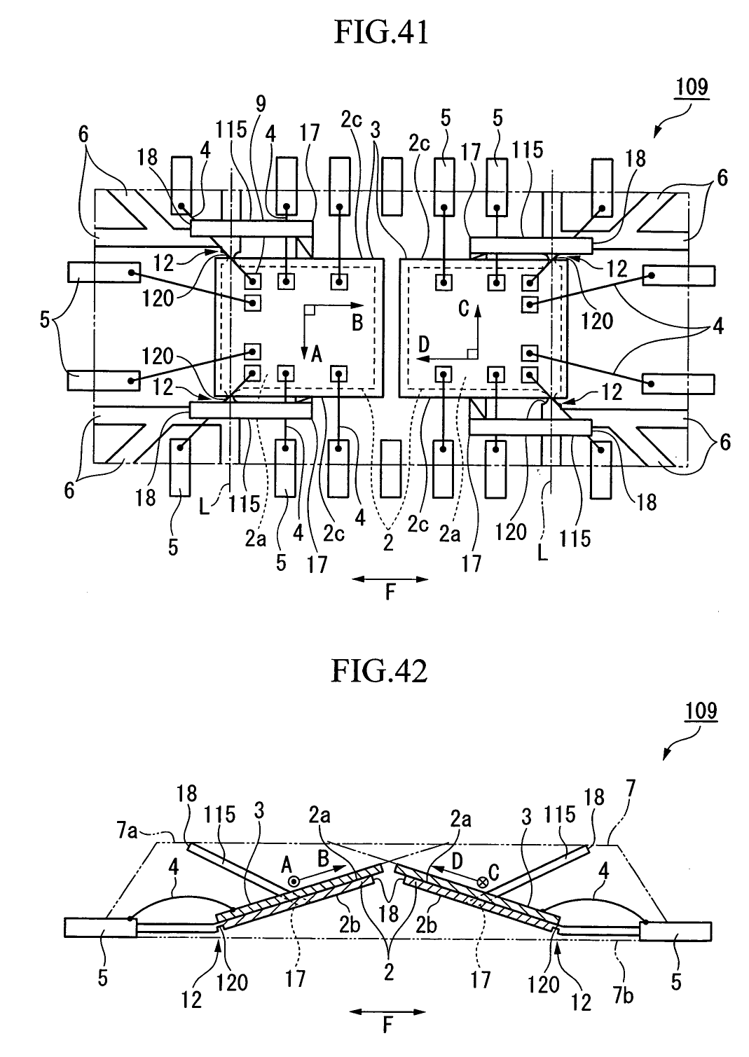

As shown in FIGS. 41 and 42, the magnetic sensor 109 according to this embodiment has two mutually tilted stages 2, magnetic sensor chips (physical sensor chips) 3 which measure the size and orientation of an external magnetic field and are respectively installed on top sides 2a of the two stages 2, leads 5 and 6 which are electrically connected by wires 4 to the magnetic sensor chips 3, and a molded resin body 7 which integrally fixes these components.

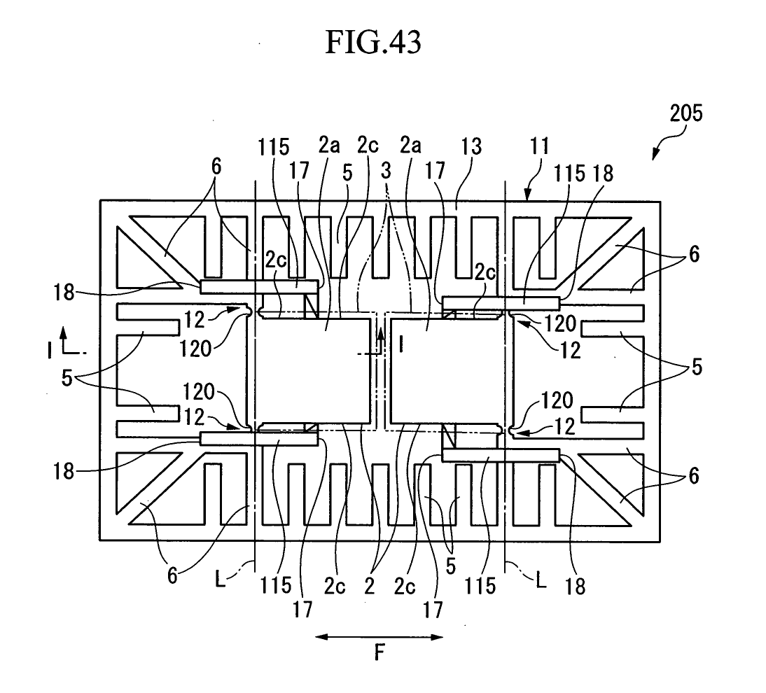

This magnetic sensor 109 is manufactured using a lead frame 205, shown in FIG. 43, having the above-mentioned stages 2 and leads 5 and 6.

The lead frame 205 is formed by pressworking, etching or otherwise shaping sheet metal such as sheet copper. As shown in FIG. 43, the lead frame 205 has two stages 2 of rectangular shape, a frame 11 having a plurality of leads 5 and 6 disposed about the periphery of these stages 2, and pairs of connecting members 12 which connect the frame 11 and the stages 2 and which are disposed opposite each other across the stages 2 on proximal edges of the stages 2.

The frame 11 has a border 13 which has been given a rectangular shape as seen in a plan view so as to surround the stages 2, and a plurality of leads 5 and 6 which project inward from this rectangular border 13.

Of the plurality of leads 5 and 6, some of the leads 6 function as suspension leads for securing the stages 2 to the rectangular border 13, and are connected to the stages 2 through the connecting members 12.

The two stages 2 are arranged side-by-side in the lengthwise direction F of the rectangular border 13, with the distal edges thereof disposed so as to be in mutual opposition. The respective stages 2 are connected at their proximal edges to the leads 6 through the pairs of connecting members 12. The magnetic sensor chips 3 are mounted on the top sides 2a of the respective stages 2.

As shown in FIG. 41, these magnetic sensor chips 3 are both sensitive to the magnetic components of the external magnetic field in two directions. The sensitive directions in one of these magnetic sensor chips 3 are mutually orthogonal directions along the surface of the magnetic sensor chip 3 (direction A and direction B), and the sensitive directions in the other magnetic sensor chip 3 are mutually orthogonal directions along the surface of that magnetic sensor chip 3 (direction C and direction D). Directions A and C are both parallel to the axis L and of opposite orientation, and directions B and D are both perpendicular to the axis L and of opposite orientation.

Alternatively, the other magnetic sensor chip 3 may be of a type having only direction D sensitivity. It is also possible for the other magnetic sensor chip 3 to be mounted horizontally.

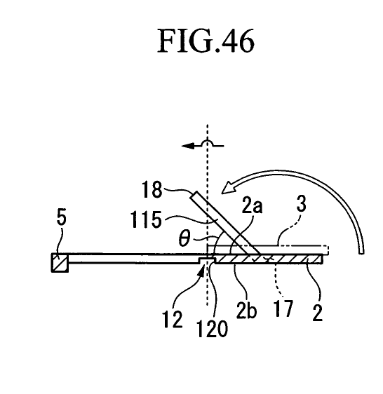

In the lead frame 205, as shown in FIG. 43, each stage 2 has top projecting members 115 which extend in an L shape as seen in a top plan view along the lengthwise direction F. The proximal ends 17 of these top projecting members 115 are respectively connected to both lateral edges 2c of each stage 2. These top projecting members 115 are integrally formed with each stage 2 and, as shown in FIGS. 42 and 46, project out on the top side 2a thereof and are tilted with respect to the stage 2.

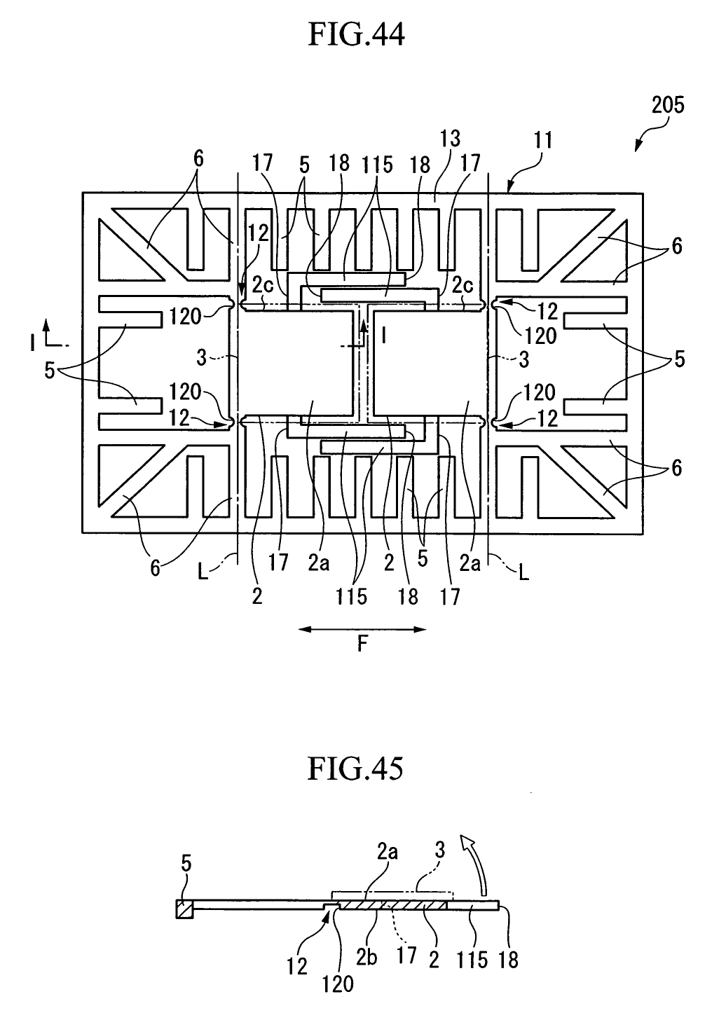

The top projecting members 115 are formed as described below. As shown in FIG. 44, when the lead frame 205 is formed by an operation such as pressworking or etching, the distal ends 18 of the top projecting members 115 are formed so as to be oriented toward the other, opposing, stage 2. In this state, the top projecting members 115 are alternately arranged along the direction of the axis L. When the distal ends 18 thereof are raised up, the proximal ends 17 twist as shown in FIGS. 45 and 46, causing the top projecting members 115 to rotate toward the top sides 2a of the stages 2 about their proximal ends 17. The top projecting members 115 are stopped at a predetermined position so as to be tilted with respect to the stages 2. As shown in FIG. 46, the angle θ at this time between the line segment connecting the distal end 18 and the proximal end 17 and the line segment connecting the proximal end 17 and the twisting portion (deforming portion) 120 of the connecting member 12 is set at an acute angle (less than 90°). The distal end 18 is thus disposed in a position which, in the direction from the proximal end 17 toward the twisting portion 120, lies beyond the twistable portion 120; i.e., is further away than the twisting portion 120.

The twisting portions 120 are recessed notches provided on the lateral edges of the connecting members 12, and are formed so as to be narrower than other portions of the leads 5 and 6. These twisting portions 120 are more easily deformed and twisted than the top projecting members 115.

Next, the steps in the production of a magnetic sensor 109 using the above-described lead frame 205 will be described. As shown in FIG. 43, in the lead frame 205, the top projecting members 115 are in an already tilted state with respect to the stages 2.

First, a magnetic sensor chip 3 is bonded to the top surface 2a of each stage 2. The magnetic sensor chip 3 is bonded so that the sensitive directions are as shown in FIG. 41.

Next, the bonding pads 9 for the magnetic sensor chips 3 are connecting to the leads 5 by wires 4, thereby electrically connecting the magnetic sensor chips 3 and the plurality of leads 5. When the stages 2 are tilted, the relative positions of the magnetic sensor chips 3 and the bonding portions of the leads 5 change. Hence, it is desirable for the wires 4 to be made of a material that is flexible and bends easily.

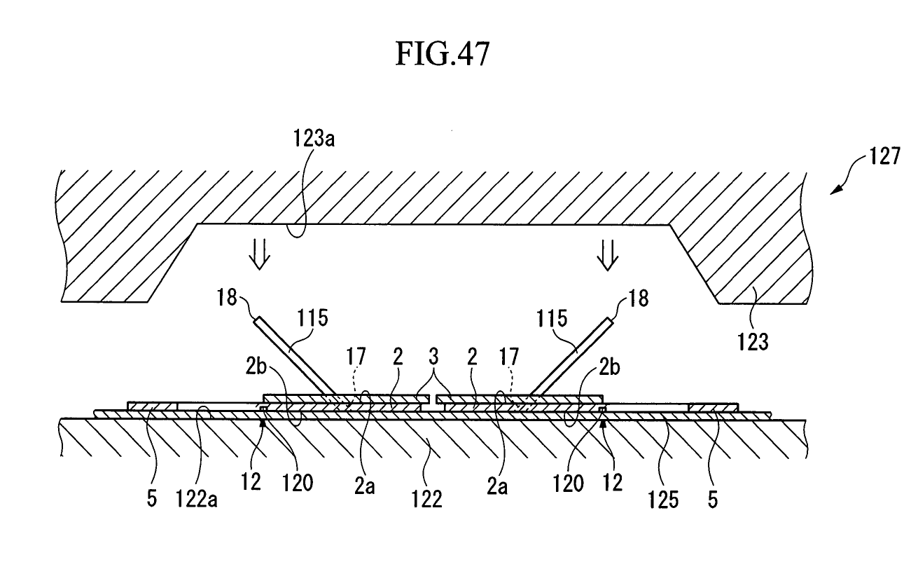

Next, as shown in FIG. 47, using a mold 127, resin molding is carried out to integrally fix the magnetic sensor chips 3, the stages 2 and the leads 5 and 6. This resin molding operation is one step in the magnetic sensor chip 3 packaging process.

The mold 127 is composed of a bottom half 122 having a flat surface 122a and a top half 123 in which a recess 123a is formed. The top mold half 123 is provided so that it can be raised and lowered with respect to the bottom mold half 122. When the top mold half 123 is lowered and the mold is clamped shut, a cavity for shaping a molded resin body 7 forms between the recess 123a and the flat surface 122a.

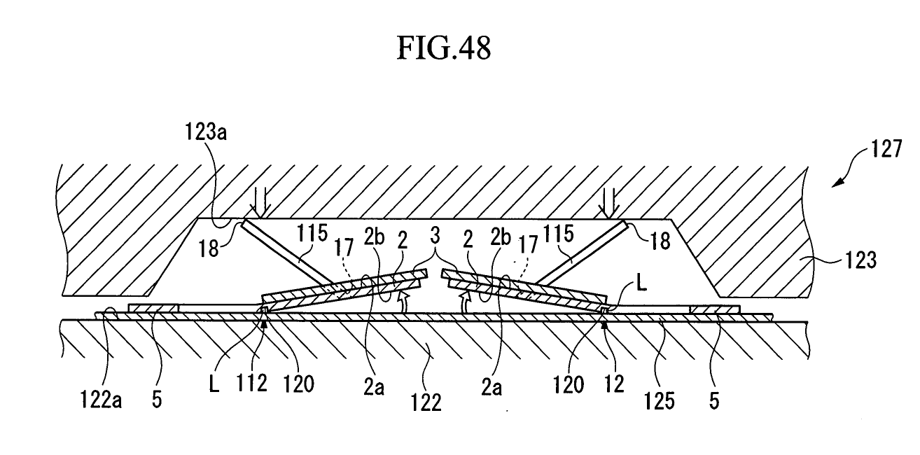

In this arrangement, the rectangular border 13 of the lead frame 205 is placed at a given position on the bottom mold half 122 over an intervening sheet mold 125. At this time, the top projecting members 115 are placed in a state that projects upward. When the top mold half 123 is lowered onto the bottom mold half 122, the surface of the recess 123a comes into contact with the distal ends 18. From this point on, as shown in FIG. 48, further lowering of the top mold half 123 causes the distal ends 18 of the top projecting members 115 to be pushed down from the top sides 2a toward the bottom sides 2b of the stages 2 by the top mold half 123. When this happens, force is applied at the distal end 18 and the twisting portion 120 serves as the fulcrum, causing a force to act upon the proximal end 17.

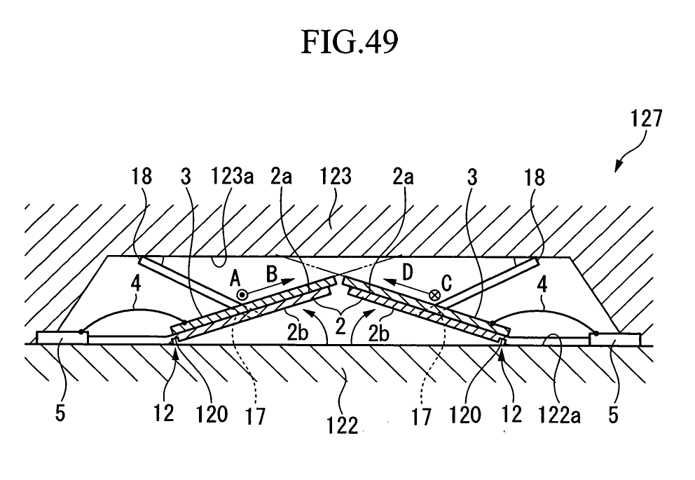

The distal end 18 lies beyond the twisting portion 120, and so this force is directed from the bottom side 2b toward the top side 2a of the stage 2. Because the twisting portion 120 deforms and twists more easily than the top projecting members 115, when the distal ends 18 are pushed down, the twisting portions 120 twist before the top projecting members 115 bend, thereby raising the distal edges of the stages 2. That is, based on the principle of a lever, each stage 2 rotates toward the top side 2a thereof around an axis L that passes through the twisting portion 120. In addition, when the top mold half 123 is lowered and the mold is closed, as shown in FIG. 49, the stages 2 becomes tilted to a given angle with respect to the flat surface 122a within the cavity. Because the top projecting members 115 are arranged side by side along the axes L, both stages 2 tilt along the respective axes L.

Resin is injected into the cavity when the stages 2 are in this tilted state, thereby forming a molded resin body 7 which covers the magnetic sensor chips 3. The magnetic sensor chips 3 are thus fixed at the interior of the molded resin body 7 in a mutually tilted state. This completes the packaging of the magnetic sensor chips 3. To keep the tilt angles of the magnetic sensor chips 3 and the stages 2 from changing as a result of resin flow, it is desirable for the resin to be a material having a high fluidity.

Lastly, the leads 5 and 6 that protrude outside of the resin molded body 7 are trimmed together with the rectangular border 13 and individually separated, after which the molded resin body 7 is removed from the mold 127, giving the magnetic sensor 109 shown in FIGS. 41 and 42. In this magnetic sensor 109, the stages 2 and the magnetic sensor chips 3 mounted on the stages 2 are tilted with respect to the bottom side 7b of the molded resin body 7. Also, because the top projecting members 115 in the magnetic sensor 109 are pushed down by the top mold half 123, the distal ends of the top projecting members 115 are in contact with the top side 7a of the molded resin body 7. That is, the top projecting members 115 extend from the stages 2 out to the top side 7a of the molded resin body 7.

In the lead frame 205 and the magnetic sensor 109 of the present embodiment, because the top projecting members 115 are provided so as to project out on the top sides 2a of the stages 2, when resin molding is complete, the distal ends 18 can be prevented from extending beyond the bottom surface of the molded resin body 7. As a result, when this magnetic sensor 109 is mounted on a substrate in a handheld device such as a cellular phone, the magnetic sensor 109 can be mounted on the substrate without damaging the substrate or shorting various electronic components on the substrate. This in turn makes it possible to improve the production yield during mounting.

Also, with geomagnetic sensor chips 3, the direction of geomagnetism can be detected as a vector in three-dimensional space, enabling the azimuth of the measured geomagnetism to be displayed on a display panel or the like. In this way, various navigation functions that utilize geomagnetism can be added to handheld devices.

The above embodiments were described using magnetic sensors as examples. However, the invention is not limited to magnetic sensor, and can also be applied to various other types of physical sensors, including acceleration sensors.

The technical scope of the present invention is not limited by the foregoing embodiment, which can be variously modified and altered without departing from the gist of the invention.

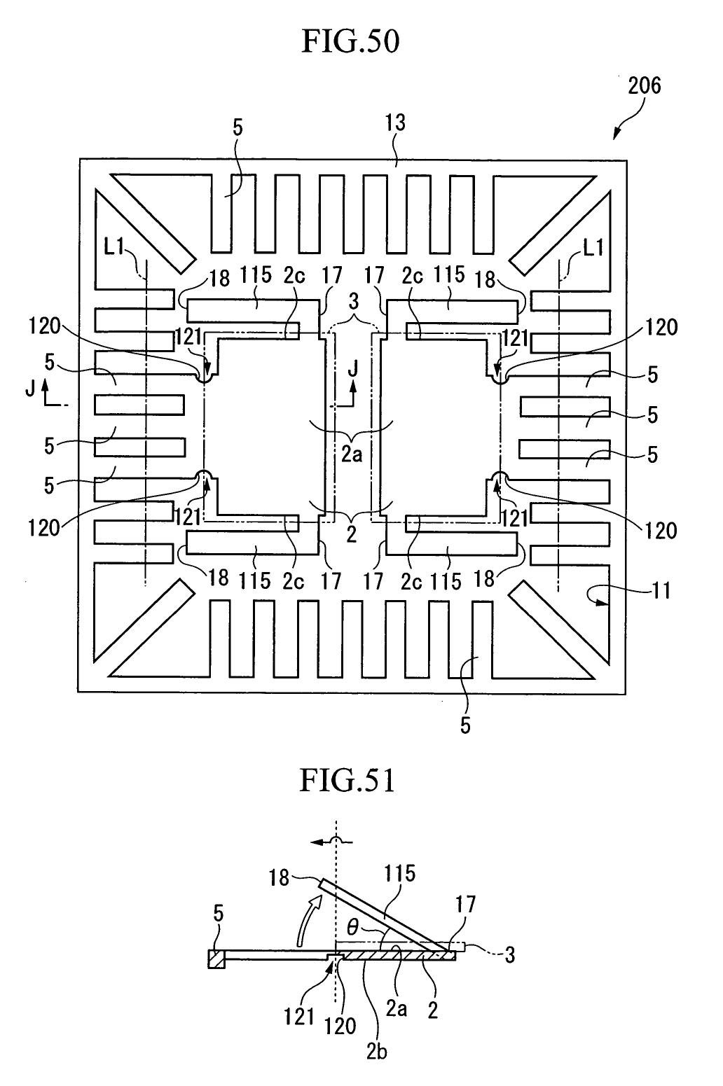

For example, as illustrated by the lead frame 206 shown in FIG. 50, it is possible to provide connecting members 121 at the proximal edges of the stages 2 and have the distal ends 18 of top projecting members 115 formed so as to face the proximal edges of the stages 2. In such an arrangement, as shown in FIG. 51, the top projecting members 115 are tilted by elevating the distal ends 18 exactly a predetermined angle θ.

In this way, not only is it possible to achieve the same results as described above, because the projecting members 115 can be set to a greater length, the tilt angle can be increased.

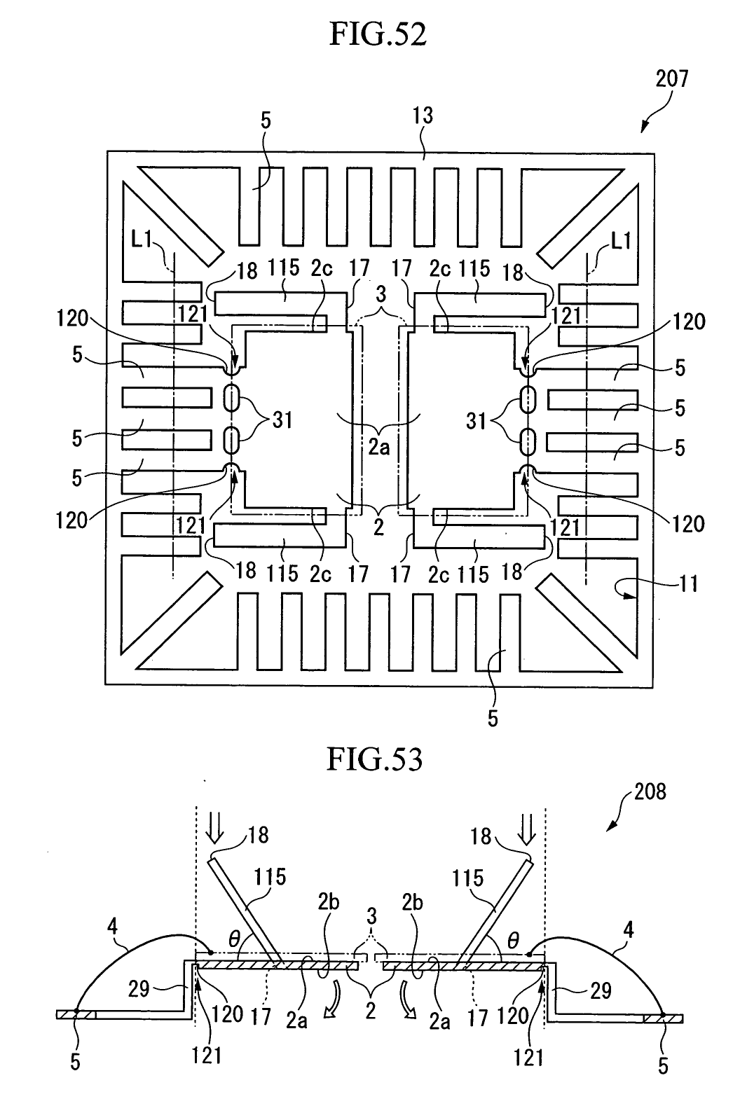

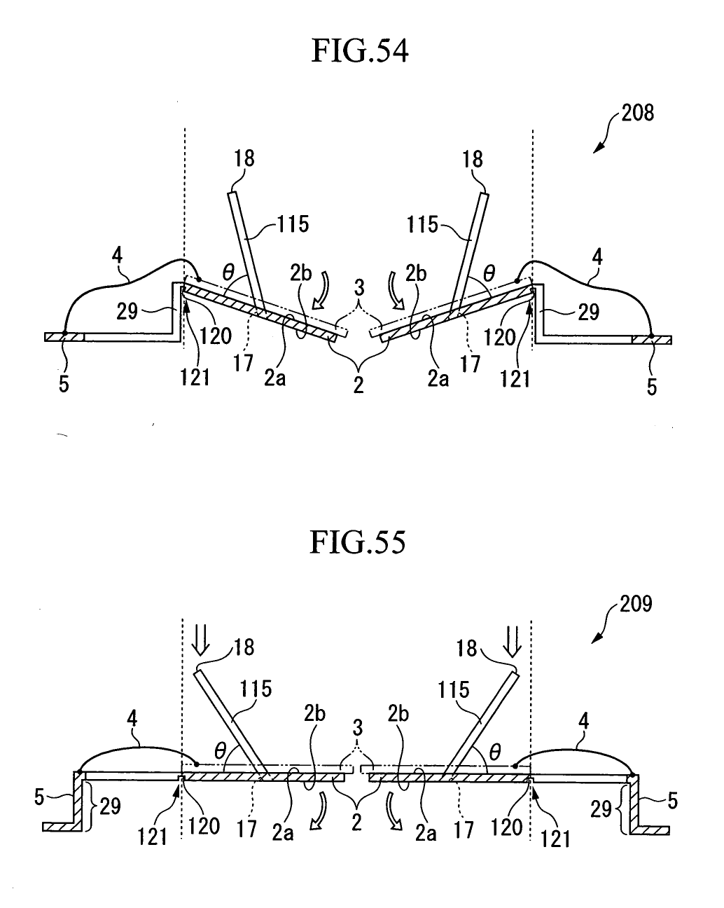

As shown in FIG. 52, the connecting members 121 may be provided with throughholes 31 oriented in the thickness direction of the lead frame 207, or the connecting members 121 may be given a small thickness. Either arrangement enables the twisting portions 120 to be easily twisted. It is also possible to both give the connecting members 121 a small thickness and form throughholes 31 therein.

As shown in FIG. 53, the distal ends 18 of the top projecting members 115 may be disposed at positions which do not extend beyond the twisting portions 120 in the direction from the proximal ends 17 thereof toward the connecting members 12. That is, in the direction from the proximal ends 17 toward the twisting portions 120, the distal ends 18 may be disposed somewhere between the proximal ends 17 and the twisting portions 120. An arrangement in which the connecting members 121 are each provided with a rise 29 by a pressworking operation, thereby offsetting the stages 2 on the top side 2a, is also possible.

In this arrangement, pushing on the distal ends 18 of the top projecting members 115 causes a force to act from the top side 2a toward the bottom side 2b at the proximal ends 17. As a result, the distal edges of the stages 2 are pushed down, causing the stages 2 to tilt in the directions of the arrows.

This arrangement, in addition to achieving the same effects as described above, allows the top projecting members 115 to be shortened by the amount to which the stages 2 are offset, thus facilitating miniaturization of the magnetic sensor 109. Moreover, the stages 2 are tilted so that the distal edges thereof are oriented downward, moving the back edges of the magnetic sensor chips 3 away from the leads 5. This allows the distance between the magnetic sensor chips 3 and the leads 5 to be decreased, enabling the lead frame 208 to be miniaturized.

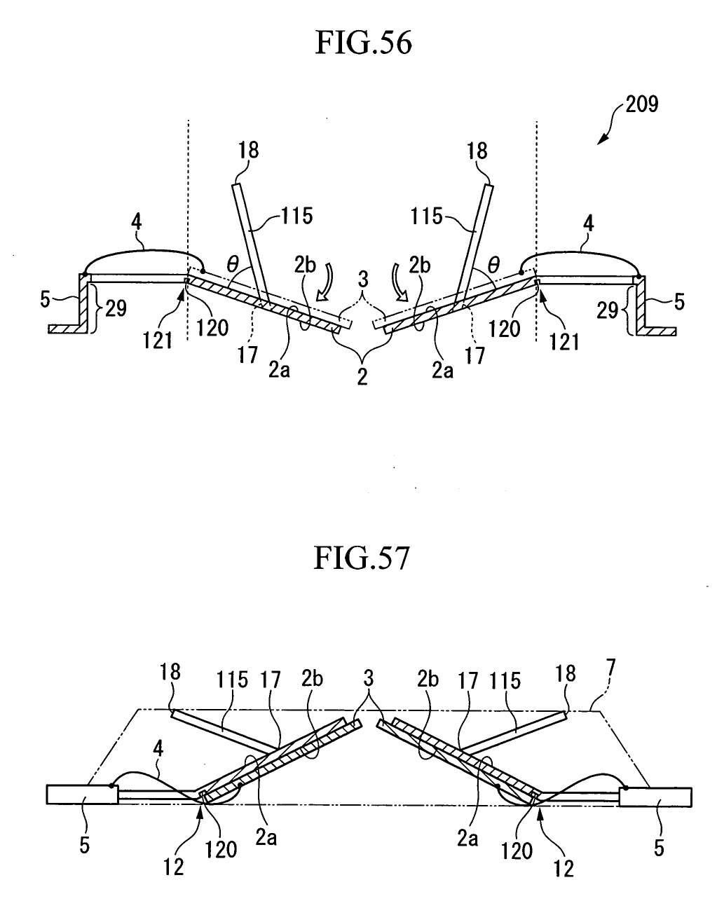

Alternatively, as shown in FIGS. 55 and 56, rises 29 may be provided in the leads 5. Such an arrangement enables the top sides of the magnetic sensor chips 3 and the surfaces of the leads 5 to be substantially matched in height, facilitating connection between the magnetic sensor chips 3 and the leads 5. Moreover, the length of the wires 4 decreases and the amount of wire deformation when the magnetic sensor chips 3 are tilted can be reduced, enabling reliability to be enhanced.

As shown in FIG. 57, it is also possible to install the magnetic sensor chips 3 on the bottom sides 2b of the stages 2.

In this arrangement, there is no interference between the projecting members 115 and the wires 4, making it possible to facilitate connection between the magnetic sensor chips 3 and the leads 5.

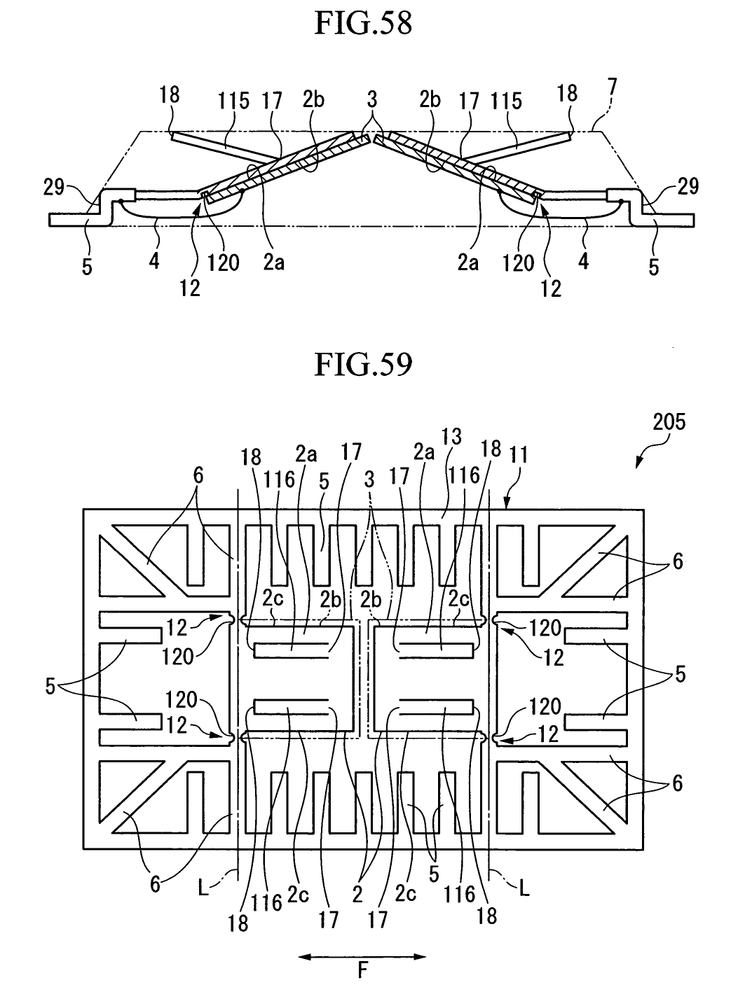

Also, as shown in FIG. 58, rises 29 may be provided in the leads 5 in addition to the arrangement shown in FIG. 57.

By so doing, wire bonding between the magnetic sensor chips 3 and the leads 5 can be facilitated and the surface exposure of wires 4 at the bottom side of the molded resin body 7 can be prevented.

In addition, as shown in FIG. 59, it is possible to place the magnetic sensor chips 3 on the bottom sides 2b of the stages 2 and to provide top projecting members 116 on the top sides 2a thereof by a slitting and forming operation.

This arrangement enables the space between the stages 2 and the leads 5 in the direction perpendicular to the axis L to be made smaller, and is thus conducive to miniaturization of the lead frame 205.

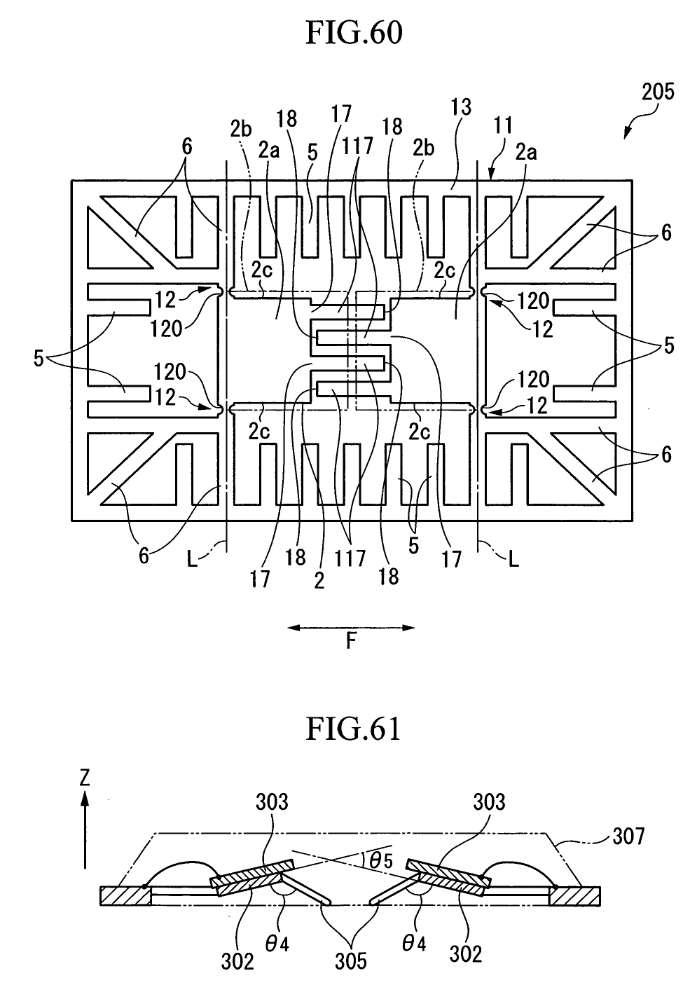

As shown in FIG. 60, when the magnetic sensor chips 3 are placed on the bottom sides 2b of the stages 2, the top projecting members 117 may be integrally formed on the distal edges of the stages 2.

Here too, the space between the stages 2 and the leads 5 in the direction perpendicular to the axis L can be made smaller, and so this arrangement also is conducive to miniaturization of the lead frame 205.

In all of the embodiments described above, the stages 2 were rectangularly formed as seen in a plan view. However, the stages 2 are not limited to such a shape, and may be given any shape onto the surface of which at least the magnetic sensor chips 3 are bondable. For example, the stages may be circular or elliptical as seen in a plan view, and may have a hole passing therethrough in the thickness direction or may be formed as a mesh.

Also, the physical sensor according to the invention has been exemplified in the foregoing embodiments by magnetic sensors which detect the magnetic direction in three-dimensional space. However, the inventive physical sensor is not limited to a magnetic sensor. As used herein, “physical sensor” refers to any sensor capable of measuring at least the direction or orientation of a physical value within three-dimensional space. Illustrative examples include acceleration sensors which contain acceleration sensor chips that detect the magnitude and direction of acceleration.

In the lead frames according to the invention, because the stage is readily deformable in the direction of a greater tilt angle, it is possible to prevent a decrease in the sensitivity of detection by the physical sensor chips in the Z direction, i.e., the direction orthogonal to the sheet metal.

Also, the physical sensors according to the invention are capable of measuring physical values such as magnetism to a high precision in all directions in three-dimensional space.

What is claimed is:

1. A lead frame made of sheet metal, comprising a stage with a top side for mounting a physical sensor chip thereon; a frame having a plurality of leads disposed peripherally around said stage; a pair of connecting members which connect said frame and said stage, are oppositely disposed across said stage at a proximal edge thereof, and are adapted for deforming said stage about an axis that mutually connects said connecting members; and a plate-like bending member which is provided on a bottom side of said stage at said proximal edge thereof and is bent to an angle with said bottom side of said stage of up to 90°.

2. The lead frame according to claim 1, wherein said bending member, when bent, is positioned within a region occupied by said stage.

3. The lead frame according to claim 1, wherein said bending member has near said stage a depression that is recessed in the thickness direction.

4. The lead frame according to claim 1 which has a plurality of said bending members.

5. The lead frame according to claim 1, wherein said stage has a projecting member which projects out on said bottom side of said stage at an angle of more than 90° therewith from at least a distal edge or both lateral edges of said stage.

6. A physical sensor which is manufactured using said lead frame according to claim 1, comprising said stage, said physical sensor chip placed on said top side of said stage, said leads which are electrically connected to said physical sensor chip, and a molded resin body which integrally fixes said stage, said physical sensor chip and said leads.

7. The lead frame according to claim 1, wherein said stage further has a top projecting member which projects out at a tilt on said top side of said stage.

8. The lead frame according to claim 7, wherein said connecting members have deforming portions which deform more easily than said top projecting member and said bending member.

9. The lead frame according to claim 7, wherein said connecting members are disposed at said proximal edge of said stage, said bending member is disposed such that a proximal end thereof is positioned at a distal edge of said stage, and said top projecting member is disposed such that a proximal end thereof is positioned at said distal or proximal edge of said stage.

10. The lead frame according to claim 7, wherein said bending member and said top projecting member are disposed so that the respective proximal ends thereof are situated on either side of said connecting members, and said stage is offset on said top side thereof.

11. The lead frame according to claim 7, wherein said bending member has near said stage a depression that is recessed in the thickness direction.

12. The lead frame according to claim 7 which has a plurality of said bending members and a plurality of said projecting members.

13. A physical sensor which is manufactured using said lead frame according to claim 7, comprising said stage, said physical sensor chip placed on said top side or bottom side of said stage, said leads which are electrically connected to said physical sensor chip, and a molded resin body which integrally fixes said stage, said physical sensor chip and said leads.

14. A physical sensor which is manufactured using said lead frame according to claim 7, comprising said stage, said physical sensor chip placed on said top side or bottom side of said stage, said leads which are electrically connected to said physical sensor chip, and an exterior wall member which fixes at least said lead frame and contacts said top projecting member and said bending member.

15. A lead frame made of sheet metal, comprising a stage for mounting a physical sensor chip, a frame having a plurality of leads disposed near said stage, and a connecting member which connects said frame and said stage and has a deforming portion;
wherein said stage has a projecting member which projects out at a tilt on a top side of said stage, and said stage is set so that a line segment connecting distal and proximal ends of said projecting member forms an acute angle with a line segment connecting said proximal end and said deforming portion.

16. The lead frame according to claim 15, wherein said deforming portion is more easily deformable than said proximal end of said projecting member.

17. The lead frame according to claim 15, wherein said distal end of said projecting member is situated, in a direction from said proximal end toward said deforming portion, at a position removed from said deforming portion.

18. The lead frame according to claim 15, wherein said distal end is situated between said proximal end and said deforming portion in a direction from said proximal end to said deforming portion, and said stage is offset on said top side thereof.

19. The lead frame according to claim 15, wherein said physical sensor chip is mounted on a bottom side of said stage.

20. The lead frame according to claim 19, wherein said projecting member is provided on said top side of said stage by a slitting and forming operation.

21. A physical sensor which is manufactured using a lead frame made of sheet metal and comprising a stage for mounting a physical sensor chip, a frame having a plurality of leads disposed near said stage, and a connecting member that connects said frame and said stage and has a deforming portion, in which said physical sensor chip is mounted at said stage, and in which said physical sensor chip and said leads are electrically connected and said stage, said physical sensor chip, said frame having a plurality of leads and said connecting member are integrally fixed by a molded resin body;
wherein said stage has a projecting member which is tilted with respect to said stage and extends to substantially a top side of said molded resin body;
said stage is tilted with respect to a bottom side of said molded resin body about an axis composed in part of said deforming portion of said connecting member; and
a line segment connecting distal and proximal ends of said projecting member forms an acute angle with a line segment connecting said proximal end and said deforming portion.

22. A physical sensor chip packaging process comprising the steps of mounting a physical sensor chip in said lead frame according to claim 15, then molding resin about the mounted physical sensor chip;
wherein closing a mold for molding said resin causes said projecting member to come into contact with and press against an inside face of said mold, thereby deforming said deforming portion of said connecting member and tilting said stage, and
resin molding is carried out with said stage held in a tilted state.
